(19) United States
(12) Patent Application Publication
(10) Pub. No.: US 2025/0048892 A1
(43) Pub. Date: Feb. 6, 2025

(54) DISPLAY PANEL, DISPLAY DEVICE AND METHOD OF MANUFACTURING DISPLAY PANEL

(71) Applicant: Hefei Visionox Technology Co., Ltd., Hefei (CN)

(72) Inventor: Liusong NI, Hefei (CN)

(73) Assignee: Hefei Visionox Technology Co., Ltd., Hefei (CN)

(21) Appl. No.: 18/910,179

(22) Filed: Oct. 9, 2024

Related U.S. Application Data
(63) Continuation of application No. PCT/CN2024/098407, filed on Jun. 11, 2024.

(30) Foreign Application Priority Data
Jul. 31, 2023 (CN) 202310966067.X

(51) Int. Cl. H10K 59/80; H10K 59/12; H10K 59/122; H10K 102/00

(52) U.S. Cl. CPC H10K 59/873; H10K 59/1201; H10K 59/122; H10K 2102/351

(57) ABSTRACT

A display panel, a display device and a method of manufacturing a display panel. The display panel includes a substrate, an isolation structure and a light-emitting function layer. The light-emitting function layer includes a first light-emitting structure and a second light-emitting structure. A thickness of the second light-emitting structure is larger than that of the first light-emitting structure in a thickness direction. The isolation structure includes a first portion and a second portion. An orthographic projection of the first portion on the substrate is located within an orthographic projection of the second portion on the substrate. A length of a portion of the second portion protruding from the first portion towards a side facing the first opening is L1, a length of a portion of the second portion protruding from the first portion towards a side facing the second opening is L2, and L1<L2.

### CROSS REFERENCE TO RELATED APPLICATION

The present application is a continuation of International Application No. PCT/CN2024/098407, filed on Jun. 11, 2024, which claims priority to Chinese Patent Application No. 202310966067.X, filed on Jul. 31, 2023, titled with “DISPLAY PANEL, DISPLAY DEVICE AND METHOD OF MANUFACTURING DISPLAY PANEL”, all of which are hereby incorporated by reference in their entireties.

### TECHNICAL FIELD

The present application relates to the technical field of display, and in particular to a display panel, a display device and a method of manufacturing a display panel.

### BACKGROUND

A flat display panel, such as a display panel based on the technical of Organic Light Emitting Diode (OLED), Light Emitting Diode (LED), has the advantages such as high image quality, low power consumption, thin body and wide application range, thus is widely used in various consumer electronic products such as a mobile phone, a television, a laptop and a desktop computer, and becomes a main stream in a display device.

However, the reliability of the display panel in the related art needs to be improved.

### SUMMARY

Embodiments of the present application provide a display panel, a display device and a method of manufacturing a display panel, which can improve the reliability of the display panel.

In an aspect, embodiments of the present application provide a display panel including: a substrate; an isolation structure, arranged on a side of the substrate in a thickness direction thereof, the isolation structure surrounding and forming a plurality of openings, and the plurality of openings including a first opening and a second opening; a light-emitting function layer, arranged on the substrate, the light-emitting function layer including a plurality of light-emitting structures, the plurality of light-emitting structures including a first light-emitting structure arranged in the first opening and a second light-emitting structure arranged in the second opening, a thickness of the second light-emitting structure being larger than a thickness of the first light-emitting structure in the thickness direction; and a first encapsulation layer, including a plurality of encapsulation portions corresponding to the light-emitting structures, respectively, and the encapsulation portions being located on a side of the light-emitting structures away from the substrate. The isolation structure includes a first portion and a second portion sequentially arranged in a direction away from the substrate, an orthographic projection of the first portion on the substrate is located within an orthographic projection of the second portion on the substrate, a length of a portion of the second portion protruding from the first portion towards a side facing the first opening is L1, a length of a portion of the second portion protruding from the first portion towards a side facing the second opening is L2, and L1<L2.

Preferably, the plurality of openings further include a third opening, the plurality of light-emitting structures further include a third light-emitting structure arranged in the third opening, and colors of light emitted by the first light-emitting structure, the second light-emitting structure and the third emitting structure are different from one another.

Preferably, the light emitted by the first light-emitting structure includes blue light, the light emitted by the second light-emitting structure includes green light, and the light emitted by the third light-emitting structure includes red light.

Preferably, each of a light-emitting area of the first light-emitting structure and a light-emitting area of the third light-emitting structure is larger than a light-emitting area of the second light-emitting structure, and/or the light-emitting area of the third light-emitting structure is smaller than the light-emitting area of the first light-emitting structure.

Preferably, the plurality of encapsulation portions are spaced apart from one another and include a first encapsulation portion located on a side of the first light-emitting structure away from the substrate, a second encapsulation portion located on a side of the second light-emitting structure away from the substrate, and an orthographic projection of the first encapsulation portion on the substrate is spaced apart from an orthographic projection of the second encapsulation portion on the substrate.

Preferably, the first encapsulation layer includes an inorganic material.

Preferably, the display panel further includes a second encapsulation layer, the second encapsulation layer is arranged on a side of the first encapsulation layer away from the substrate, and the second encapsulation layer covers the plurality of encapsulation portions.

Preferably, at least a portion of the second encapsulation layer is filled in the first gap, the second gap and the third gap.

Preferably, the second encapsulation layer includes an organic material.

Preferably, the display panel further includes a third encapsulation layer, the third encapsulation layer is located on a side of the second encapsulation layer away from the substrate.

Preferably, the third encapsulation layer includes an inorganic material.

Preferably, the plurality of openings further include a third opening, the plurality of light-emitting structures further include a third light-emitting structure arranged in the third opening, and a thickness of the third light-emitting structure is larger than the thickness of the second light-emitting structure in the thickness direction.

Preferably, the plurality of encapsulation portions further include a third encapsulation portion located on a side of the third light-emitting structure away from the substrate.

Preferably, on a cross section along the thickness direction and perpendicular to an extending direction of the isolation structure disposed around a circumferential direction of the second light-emitting structure, a distance between an edge of the isolation structure located in the circumferential direction of the second light-emitting structure and an edge of the second encapsulation portion, in the direction parallel to the plane where the substrate is located, is M2; on a cross section along the thickness direction and perpendicular to an extending direction of the isolation structure disposed around a circumferential direction of the third light-emitting structure, a distance between an edge of the isolation structure located in the circumferential direction of the third light-emitting structure and an edge of the third encapsulation portion, in the direction parallel to the plane where the substrate is located, is M3; and M2<M3.

Preferably, an end of the second encapsulation portion is provided with a second surface; on a cross section along the thickness direction and perpendicular to an extending direction of the isolation structure disposed around a circumferential direction of the second light-emitting structure, an inclination angle between the second surface and the plane where the substrate is located is A2; an end of the third encapsulation portion is provided with a third surface; on a cross section along the thickness direction and perpendicular to an extending direction of the isolation structure disposed around a circumferential direction of the third light-emitting structure, an inclination angle between the third surface and the plane where the substrate is located is A3; and A2<A3.

Preferably, the display panel further includes a second electrode, the second electrode is arranged on the side of the substrate facing the isolation structure, and the second electrode is at least partially exposed from the openings and insulated from the isolation structure;

Preferably, a material of the isolation structure includes a metal material, and the first electrode is in contact with and connected to the isolation structure.

Preferably, the first portion includes a first sub-layer and a second sub-layer sequentially arranged in the direction away from the substrate, the first sub-layer protrudes from the second sub-layer towards a side facing the openings, and the first electrode is in contact with and connected to at least one of the first sub-layer and the second sub-layer.

In another aspect, embodiments of the present application provide a display panel including: a substrate; an isolation structure, arranged on a side of the substrate in a thickness direction thereof, the isolation structure surrounding and forming a plurality of openings, and the plurality of openings including a first opening and a second opening; a light-emitting function layer, arranged on the substrate, the light-emitting function layer including a plurality of light-emitting structures, the plurality of light-emitting structures including a first light-emitting structure arranged in the first opening and a second light-emitting structure arranged in the second opening, a thickness of the second light-emitting structure being larger than a thickness of the first light-emitting structure in the thickness direction; and a first encapsulation layer, including a plurality of encapsulation portions corresponding to the light-emitting structures, respectively, the encapsulation portions being located on a side of the light-emitting structures away from the substrate, the encapsulation portions being in contact with a side wall of the isolation structure facing the openings and extending to a side of the isolation structure away from the substrate along the side wall, and the plurality of encapsulation portions including a first encapsulation portion located on a side of the first light-emitting structure away from the substrate and a second encapsulation portion located on a side of the second light-emitting structure away from the substrate. In the thickness direction, at least a portion of the first encapsulation portion is spaced apart from and opposite to a surface of the isolation structure away from the substrate to form a first gap, at least a portion of the second encapsulation portion is spaced apart from and opposite to the surface of the isolation structure away from the substrate to form a second gap, and a size of the first gap in the thickness direction is smaller than a size of the second gap in the thickness direction.

Preferably, the size of the first gap is smaller than the thickness of the second light-emitting structure in the thickness direction.

Preferably, the plurality of openings further include a third opening, the plurality of light-emitting structures further include a third light-emitting structure arranged in the third opening, and a thickness of the third light-emitting structure is larger than the thickness of the second light-emitting structure in the thickness direction;

the plurality of encapsulation portions further include a third encapsulation portion located on a side of the third light-emitting structure away from the substrate, at least a portion of the third encapsulation portion is spaced apart from and opposite to the surface of the isolation structure away from the substrate to form a third gap, and the size of the second gap in the thickness direction is smaller than a size of the third gap in the thickness direction.

Preferably, the size of the second gap in the thickness direction is smaller than the thickness of the third light-emitting structure in the thickness direction.

Preferably, the size of the first gap is larger than or equal to the thickness of the first light-emitting structure in the thickness direction;

or/and the size of the second gap is larger than or equal to the thickness of the second light-emitting structure in the thickness direction;

or/and the size of the third gap is larger than or equal to the thickness of the third light-emitting structure in the thickness direction.

Preferably, the display panel further includes a second electrode, the second electrode is arranged on a side of the substrate facing the isolation structure, and the second electrode is at least partially exposed from the openings and insulated from the isolation structure;

the light-emitting structure includes an organic material layer and a first electrode located on a side of the organic material layer away from the substrate, a material of the isolation structure includes a metal material, and the first electrode is in contact with and connected to the isolation structure; and

Preferably, the isolation structure includes a first portion and a second portion sequentially arranged in a direction away from the substrate, an orthographic projection of the first portion on the substrate is located within an orthographic projection of the second portion on the substrate.

Preferably, the plurality of light-emitting structures include the first light-emitting structure, the second light-emitting structure and a third light-emitting structure, a thickness of an organic material layer of the second light-emitting structure is larger than a thickness of an organic material layer of the first light-emitting structure;

or a thickness of a first electrode of the first light-emitting structure is less than a thickness of a first electrode of the second light-emitting structure;

Preferably, a thickness of an organic material layer of the third light-emitting structure is larger than the thickness of the organic material layer of the second light-emitting structure;

or a thickness of a first electrode of the third light-emitting structure is larger than a thickness of a first electrode of the second light-emitting structure.

Preferably, a length of a portion of the second portion protruding from the first portion towards a side facing the first opening is L1, a length of a portion of the second portion protruding from the first portion towards a side facing the second opening is L2, and L1<L2.

Preferably, the plurality of openings further include a third opening, and the plurality of light-emitting structures further include a third light-emitting structure arranged in the third opening, a thickness of the third light-emitting structure is larger than the thickness of the second light-emitting structure in the thickness direction, a length of an edge of the second portion protruding from the first portion towards the third opening is L3, and L2<L3.

In another aspect, embodiments of the present application provide a display panel including: a substrate; an isolation structure, arranged on a side of the substrate in a thickness direction thereof, the isolation structure surrounding and forming a plurality of openings, and the plurality of openings including a first opening and a second opening; a light-emitting function layer, arranged on the substrate, the light-emitting function layer including a plurality of light-emitting structures, the plurality of light-emitting structures including a first light-emitting structure arranged in the first opening and a second light-emitting structure arranged in the second opening, a thickness of the second light-emitting structure being larger than a thickness of the first light-emitting structure in the thickness direction; and a first encapsulation layer, including a plurality of encapsulation portions corresponding to the light-emitting structures, respectively, the encapsulation portions being located on a side of the light-emitting structures away from the substrate, the encapsulation portions being in contact with a side wall of the isolation structure facing the openings and extending to a side of the isolation structure away from the substrate along the side wall, and the plurality of encapsulation portions including a first encapsulation portion located on a side of the first light-emitting structure away from the substrate and a second encapsulation portion located on a side of the second light-emitting structure away from the substrate. In the thickness direction, at least a portion of the first encapsulation portion is spaced apart from and opposite to a surface of the isolation structure away from the substrate to form a first gap, and a size of the first gap in the thickness direction is smaller than a thickness of the second light-emitting structure.

Preferably, at least a portion of the second encapsulation portion is spaced apart from and opposite to the surface of the isolation structure away from the substrate to form a second gap, the plurality of openings further include a third opening, the plurality of light-emitting structures further include a third light-emitting structure arranged in the third opening, and a size of the second gap in the thickness direction is smaller than a thickness of the third light-emitting structure.

In another aspect, embodiments of the present application provide a display panel including: a substrate; an isolation structure, arranged on a side of the substrate in a thickness direction thereof, the isolation structure surrounding and forming a plurality of openings, the plurality of openings including a first opening and a second opening, the isolation structure including a first portion and a second portion sequentially arranged in a direction away from the substrate, an orthographic projection of the first portion on the substrate being located within an orthographic projection of the second portion on the substrate, a length of a portion of the second portion protruding from the first portion towards a side facing the first opening being L1, a length of a portion of the second portion protruding from the first portion towards a side facing the second opening being L2, and L1<L2; a light-emitting function layer, arranged on the substrate, the light-emitting function layer including a plurality of light-emitting structures, the plurality of light-emitting structures including a first light-emitting structure arranged in the first opening and a second light-emitting structure arranged in the second opening, a thickness of the second light-emitting structure being larger than a thickness of the first light-emitting structure in the thickness direction; and a first encapsulation layer, including a plurality of encapsulation portions corresponding to the light-emitting structures, respectively, the encapsulation portions being located on a side of the light-emitting structures away from the substrate, the encapsulation portions being in contact with a side wall of the first portion facing the openings and extending to a side of the second portion away from the substrate along the side wall, and the plurality of encapsulation portions including a first encapsulation portion located on a side of the first light-emitting structure away from the substrate and a second encapsulation portion located on a side of the second light-emitting structure away from the substrate. In the thickness direction, at least a portion of the first encapsulation portion is spaced apart from and opposite to a surface of the second portion away from the first portion to form a first gap, at least a portion of the second encapsulation portion is spaced apart from and opposite to the surface of the second portion away from the first portion to form a second gap, and a size of the first gap in the thickness direction is smaller than a size of the second gap in the thickness direction.

Preferably, an orthographic projection of the first encapsulation portion on the substrate is spaced apart from an orthographic projection of the second encapsulation portion on the substrate.

Preferably, the size of the first gap in the thickness direction is smaller than the thickness of the second light-emitting structure.

Preferably, the plurality of openings further include a third opening, and the plurality of light-emitting structures further include a third light-emitting structure arranged in the third opening, a thickness of the third light-emitting structure is larger than the thickness of the second light-emitting structure in the thickness direction, a length of an edge of the second portion protruding from the first portion towards the third opening is L3, and L2<L3.

The plurality of encapsulation portions further include a third encapsulation portion located on a side of the third light-emitting structure away from the substrate, at least a portion of the third encapsulation portion is spaced apart from and opposite to the surface of the second portion away from the first portion to form a third gap, and the size of the second gap is smaller than a size of the third gap;

Preferably, the size of the second gap in the thickness direction is smaller than the thickness of the third light-emitting structure.

Preferably, the thickness of the second light-emitting structure is larger than the thickness of the first light-emitting structure, and/or the thickness of the third light-emitting structure is larger than the thickness of the second light-emitting structure.

Preferably, the size of the first gap is larger than or equal to the thickness of the first light-emitting structure in the thickness direction;

and/or the size of the second gap is larger than or equal to the thickness of the second light-emitting structure;

and/or the size of the third gap is larger than or equal to the thickness of the third light-emitting structure.

Preferably, the display panel further includes a second encapsulation layer, the second encapsulation layer is arranged on a side of the first encapsulation layer away from the substrate, the second encapsulation layer covers the plurality of encapsulation portions, and the second encapsulation layer is at least partially filled in the first gap, the second gap and the third gap.

In another aspect, embodiments of the present application provide a display panel including: a substrate; an isolation structure, arranged on a side of the substrate in a thickness direction thereof, the isolation structure surrounding and forming a plurality of openings, and the plurality of openings including a first opening and a second opening; a light-emitting function layer, arranged on the substrate, the light-emitting function layer including a plurality of light-emitting structures, the plurality of light-emitting structures including a first light-emitting structure arranged in the first opening and a second light-emitting structure arranged in the second opening, a thickness of the second light-emitting structure being larger than a thickness of the first light-emitting structure in the thickness direction; and a first encapsulation layer, including a plurality of encapsulation portions corresponding to the light-emitting structures, respectively, the encapsulation portions being located on a side of the light-emitting structures away from the substrate, and the plurality of encapsulation portions being spaced apart from one another, and including a first encapsulation portion located on a side of the first light-emitting structure away from the substrate and a second encapsulation portion located on a side of the second light-emitting structure away from the substrate. On a cross section along the thickness direction and perpendicular to an extending direction of the isolation structure disposed around a circumferential direction of the first light-emitting structure, a distance between an edge of the isolation structure located in the circumferential direction of the first light-emitting structure and an edge of an end of the first encapsulation portion, in a direction parallel to the plane where the substrate is located, is M1; on a cross section along the thickness direction and perpendicular to an extending direction of the isolation structure disposed around a circumferential direction of the second light-emitting structure, a distance between an edge of the isolation structure located in the circumferential direction of the second light-emitting structure and an edge of the second encapsulation portion, in the direction parallel to the plane where the substrate is located, is M2; and M1<M2.

Preferably, the isolation structure includes a first portion and a second portion sequentially arranged in a direction away from the substrate, an orthographic projection of the first portion on the substrate is located within an orthographic projection of the second portion on the substrate, a length of a portion of the second portion protruding from the first portion towards a side facing the first opening is L1, a length of a portion of the second portion protruding from the first portion towards a side facing the second opening is L2, and L1<L2.

Preferably, the openings further include a third opening, and the plurality of light-emitting structures further include a third light-emitting structure arranged in the third opening, a thickness of the third light-emitting structure is larger than the thickness of the second light-emitting structure in the thickness direction, the plurality of encapsulation portions further include a third encapsulation portion located on a side of the third light-emitting structure away from the substrate; on a cross section along the thickness direction and perpendicular to an extending direction of the isolation structure disposed around a circumferential direction of the third light-emitting structure, a distance between an edge of the isolation structure located in the circumferential direction of the third light-emitting structure and an edge of the third encapsulation portion, in the direction parallel to the plane where the substrate is located, is M3, and M2<M3.

Preferably, orthographic projections of the plurality of encapsulation portions on the substrate are spaced apart from one another.

Preferably, the isolation structure includes a first portion and a second portion sequentially arranged in a direction away from the substrate, an orthographic projection of the first portion on the substrate is located within an orthographic projection of the second portion on the substrate, a length of a portion of the second portion protruding from the first portion towards a side facing the second opening is L2, a length of a portion of the second portion protruding from the first portion towards a side facing the third opening is L3, and L2<L3.

In another aspect, embodiments of the present application provide a display panel including: a substrate; an isolation structure, arranged on a side of the substrate in a thickness direction thereof, the isolation structure surrounding and forming a plurality of openings, and the plurality of openings including a first opening and a second opening; a light-emitting function layer, arranged on the substrate, the light-emitting function layer including a plurality of light-emitting structures, the plurality of light-emitting structures including a first light-emitting structure arranged in the first opening and a second light-emitting structure arranged in the second opening, a thickness of the second light-emitting structure being larger than a thickness of the first light-emitting structure in the thickness direction; and a first encapsulation layer, including a plurality of encapsulation portions corresponding to the light-emitting structures, respectively, the encapsulation portions being located on a side of the light-emitting structures away from the substrate, and the plurality of encapsulation portions including a first encapsulation portion located on a side of the first light-emitting structure away from the substrate and a second encapsulation portion located on a side of the second light-emitting structure away from the substrate. On a cross section along the thickness direction and perpendicular to an extending direction of the isolation structure disposed around a circumferential direction of the first light-emitting structure, an end of the first encapsulation portion is provided with a first surface; on a cross section along the thickness direction and perpendicular to an extending direction of the isolation structure disposed around a circumferential direction of the second light-emitting structure, an end of the second encapsulation portion is provided with a second surface; an inclination angle between the first surface and a plane where the substrate is located is A1, an inclination angle between the second surface and the plane where the substrate is located is A2, and A1<A2.

Preferably, the plurality of openings further include a third opening, and the plurality of light-emitting structures further include a third light-emitting structure arranged in the third opening, a thickness of the third light-emitting structure is larger than the thickness of the second light-emitting structure in the thickness direction, the plurality of encapsulation portions further include a third encapsulation portion located on a side of the third light-emitting structure away from the substrate, an end of the third encapsulation portion is provided with a third surface; on a cross section along the thickness direction and perpendicular to an extending direction of the isolation structure disposed around a circumferential direction of the third light-emitting structure, an inclination angle between the third surface and the plane where the substrate is located is A3, and A2<A3.

Preferably, the isolation structure includes a first portion and a second portion sequentially arranged in a direction away from the substrate, an orthographic projection of the first portion on the substrate is located within an orthographic projection of the second portion on the substrate, a length of a portion of the second portion protruding from the first portion towards a side facing the second opening is L2, a length of a portion of the second portion protruding from the first portion towards a side facing the third opening is L3, and L2<L3.

Preferably, the isolation structure includes a first portion and a second portion sequentially arranged in a direction away from the substrate, an orthographic projection of the first portion on the substrate is located within an orthographic projection of the second portion on the substrate, a length of a portion of the second portion protruding from the first portion towards a side facing the first opening is L1, a length of a portion of the second portion protruding from the first portion towards a side facing the second opening is L2, and L1<L2.

In another aspect, embodiments of the present application provide a display device including the display panel as described above.

In another aspect, embodiments of the present application provide a method of manufacturing a display panel, including:
forming an isolation structure on a side of a substrate in a thickness direction thereof, the isolation structure surrounding and forming a plurality of openings, and the plurality of openings including a first opening and a second opening;
forming a first encapsulation material layer and a first light-emitting structural layer with a first thickness on the substrate and the isolation structure;
removing at least a portion of the first encapsulation material layer and a portion of the first light-emitting structural layer outside the first opening to form a first light-emitting structure located within the first opening and a first encapsulation portion covering the first light-emitting structure;
forming a second encapsulation material layer and a second light-emitting structural layer with a second thickness on the substrate and the isolation structure, the second thickness being larger than the first thickness; and
removing at least a portion of the second encapsulation material layer and a portion of the second light-emitting structural layer outside the second opening to form a second light-emitting structure located within the second opening and a second encapsulation portion covering the second light-emitting structure.

### BRIEF DESCRIPTION OF THE DRAWINGS

The features, advantages and technical effects of exemplary embodiments of the present application will be described below with reference to the drawings.

FIG. 1 is a top view of a display panel according to an embodiment of the present application;

FIG. 2 is a structural schematic cross-sectional view of the display panel along a direction of line B-B shown in FIG. 1 according to an embodiment of the present application;

FIG. 3 is a partial enlarged view at point A shown in FIG. 2;

FIG. 4 is a partial enlarged view of a display panel according to an embodiment of the present application;

FIG. 5 is a structural schematic cross-sectional view of a display panel according to another embodiment of the present application;

FIG. 6 is a structural schematic cross-sectional view of a display panel according to another embodiment of the present application;

FIG. 7 is a structural schematic view of a display panel according to an embodiment of the present application;

FIG. 8 is a structural schematic view of a display panel according to another embodiment of the present application;

FIG. 9 is a structural schematic view of a display panel according to another embodiment of the present application;

FIG. 10 is a flowchart of a method of manufacturing a display panel according to an embodiment of the present application; and

FIG. 11 to FIG. 18 are structural schematic views corresponding to steps of a method of manufacturing a display panel according to an embodiment of the present application.

### REFERENCE NUMERALS

10. substrate;
20. isolation structure; 21. first portion; 211, first sub-layer; 212. second sub-layer; 22. second portion; 23. opening; 23a. first opening; 23b. second opening; 23c. third opening;
30. light-emitting function layer; 31. light-emitting structure; 31a. first light-emitting structure; 31b. second light-emitting structure; 31c. third light-emitting structure; 311. organic material layer; 312. first electrode;
40. first encapsulation layer; 41. encapsulation portion; 41a. first encapsulation portion 41b, second encapsulation portion; 41c. third encapsulation portion;
50. second encapsulation layer; 60. third encapsulation layer; 70. pixel-limiting layer; 80. second electrode;
91. first gap; 92. second gap; 93. third gap;
110. first light-emitting structural layer; 120. first encapsulation material layer; 130. colloid; X-thickness direction.

In the drawings, the same component is marked with the same reference numeral. The drawings are not drawn to the actual scale.

### DETAILED DESCRIPTION

Features and exemplary embodiments in various aspects of the present application will be described in detail below. In order to make the objects, technical solutions and advantages of the present application clearer, the present application will be further described in detail below in conjunction with the drawings and the specific embodiments. It should be understood that the specific embodiments described here are only configured to explain the present application, not to limit the present application. It is apparent to one skilled in the art that the present application can be practiced without some of these specific details. The description of the embodiments below is only to provide a better understanding of the present application by showing examples of the present application.

It should be noted that, in this context, relational terms such as first and second are merely used to distinguish one entity or operation from another entity or operation, and do not necessarily require or imply any such actual relationship or order between the entities or operations. Further, the term “comprise”, “include” or any other variations thereof is intended to encompass a non-exclusive inclusion, such that a process, method, article, or device including a plurality of elements includes not only these elements but also other elements not listed, or elements that are inherent to such process, method, article or device. Without more limitations, an element that is defined by an expression “comprises . . . ” does not exclude other identical elements in the process, method, article, or device comprising this element.

It should be understood that when the structure of a part is described, the expression of one layer or region being located “on” or “above” other layer or region may mean that one layer or region is directly located on other layer or region, or there is another layer or region between the one layer or region and the other layer or region. And if the part is flipped, the one layer or region is located “under” or “below” the other layer or region.

It is apparent to those skilled in the art that various modifications and changes can be made in the present application without deviating from the gist or scope of the present application. Therefore, the present application aims to cover the modifications and changes of the present application that fall within the scope of the corresponding claims (technical solutions to be claimed) and their equivalents. It should be noted that the embodiments of the present application can be combined with one another without contradiction.

In a related art, the display panel may be provided with an isolation structure to achieve the isolation among different light-emitting structures. However, during the use of the display panel, the display failure is prone to occur.

The inventors have found through the research that, in the process of manufacturing the display panel, due to a segment gap between an encapsulation structure and an isolation structure of a light-emitting structure with a previous thickness requirement, a cathode region cannot fully cover the encapsulation structure above sub-pixels which are previously formed after the formation of the light-emitting structures with a later required thickness. Thus, when the light-emitting structures with the later required thickness is patterned, a preserved portion of the encapsulation structure of the previous light-emitting structure may be damaged by etching, resulting in the decrease in product yield and the display failure.

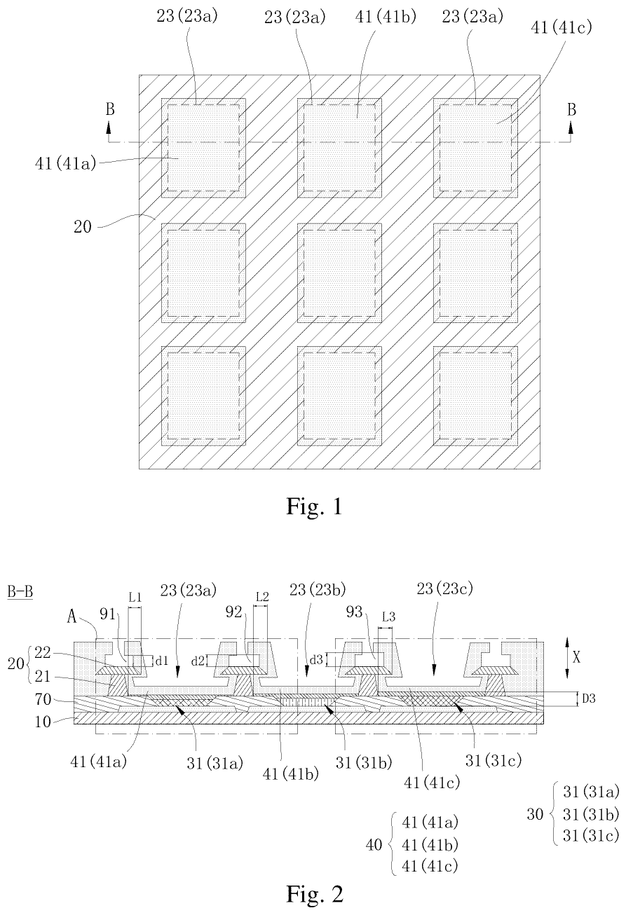

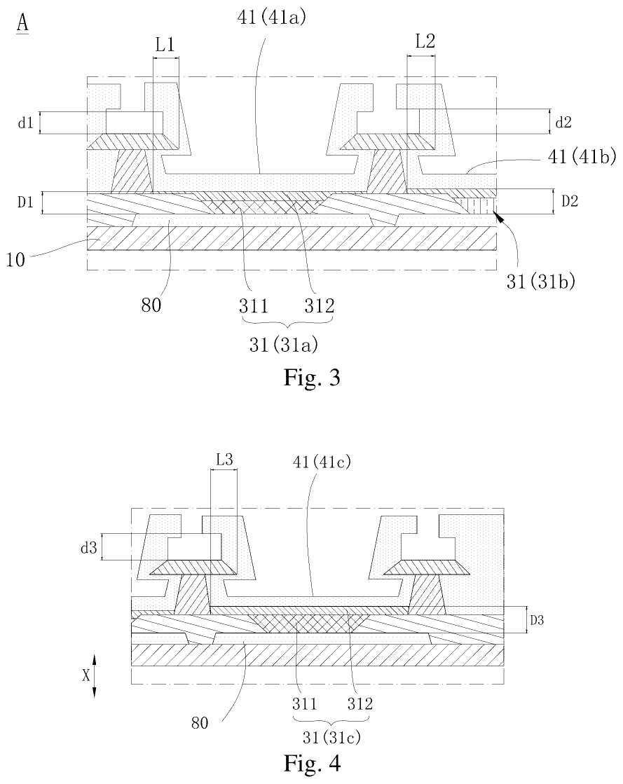

In view of this, in a first aspect, referring to FIG. 1 to FIG. 4, the embodiments of present application provide a display panel including a substrate 10; an isolation structure 20, a light-emitting function layer 30 and a first encapsulation layer 40. The isolation structure 20 is arranged on a side of the substrate 10 in a thickness direction X thereof. The isolation structure 20 surrounds and forms a plurality of openings 23, and the plurality of openings 23 include a first opening 23a and a second opening 23b. The light-emitting function layer 30 is arranged on the substrate 10, the light-emitting function layer 30 includes a plurality of light-emitting structures 31, and the plurality of light-emitting structures 31 include a first light-emitting structure 31a arranged in the first opening 23a and a second light-emitting structure 31b arranged in the second opening 23b. In the thickness direction X of the substrate 10, which can be understood that the thickness direction X of the substrate 10 is a direction perpendicular to a plane where substrate 10 is located, a thickness D2 of the second light-emitting structure 31b is larger than a thickness D1 of the first light-emitting structure 31a. The first encapsulation layer 40 includes a plurality of encapsulation portions 41 corresponding to the light-emitting structures 31, respectively. The encapsulation portions 41 are located on a side of the light-emitting structures 31 away from the substrate 10. The isolation structure 20 includes a first portion 21 and a second portion 22 sequentially arranged in a direction away from the substrate 10. An orthographic projection of the first portion 21 on the substrate 10 is located within an orthographic projection of the second portion 22 on the substrate 10. A length of a portion of the second portion 22 protruding from the first portion 21 towards a side facing the first opening 23a is L1, a length of a portion of the second portion 22 protruding from the first portion 21 towards a side facing the second opening 23b is L2, and L1<L2.

It should be noted that the first and second terms in the present application do not specifically refer to and do not mean a sequential definition, but are merely names.

The number of openings 23 can be set according to the display requirement of the display panel. There are a plurality of first openings 23a and a plurality of second openings 23b. The number of first openings 23a may be equal to the number of second openings 23b. Alternatively, the number of first openings 23a may be more than or less than the number of the second openings 23b.

The light emitted by the first light-emitting structure 31a and the light emitted by the second light-emitting structure 31b may be different, for example: the light emitted by the first light-emitting structure 31a may include blue light, and the light emitted by the second light-emitting structure 31b may include green light; or the light emitted by the first light-emitting structure 31a may include green light, and the light emitted by the second light-emitting structure 31b may include red light.

The substrate 10 may be a hard substrate 10, such as a glass substrate 10, or may be a flexible substrate 10, which can be made of polyimide, polystyrene, polyethylene terephthalate, polyethylene terephthalate, polyethylene terephthalate, polyethersulfone, or polyethylene naphthalate. The substrate 10 is mainly used to support a component arranged on it.

An array layer may be arranged between the substrate 10 and the light-emitting function layer 30, and include a driving circuit. For example, the array layer may include a first conductive layer, a second conductive layer and a third conductive layer stacked on a side of the substrate 10. An insulation layer is arranged between each two adjacent conductive layers. Exemplarily, a pixel driving circuit arranged in the array layer includes a transistor and a storage capacitor. The transistor includes a semiconductor, a gate, a source and a drain. The storage capacitor includes a first electrode plate and a second electrode plate. As an example, the gate and the first electrode plate are located in the first conductive layer, the second electrode plate is located in the second conductive layer, and the source and the drain are located in the third conductive layer.

The isolation structure 20 can be located on a pixel-limiting layer 70, or on a flattening layer. The position of the isolation structure 20 is not specifically limited here.

Optionally, the isolation structure 20 and the light-emitting function layer 30 are located on the same side of the substrate 10, and the isolation structure 20 surrounds and forms the plurality of openings 23. A size and a shape of the isolation structure 20 are not limited by the embodiments of the present application. Optionally, an orthogonal projection of the isolation structure 20 on the substrate 10 may be a mesh-like structure. Alternatively, in some embodiments, the orthogonal projection of the isolation structure 20 on the substrate 10 may be a plurality of independent circular structures, each of which is provided with the opening 23. All types of the isolation structure 20 mentioned above can meet the usage requirement of the display panel.

The plurality of openings 23 surrounded and formed by the isolation structure 20 can correspond to the light-emitting structures 31 respectively, that is, one light-emitting structure 31 is located within each of openings 23. Alternatively, the plurality of light-emitting structures 31 can be arranged within one opening 23, for example, the plurality of light-emitting structures 31 with the same color can be arranged within one opening 23.

The first encapsulation layer 40 can be used to protect the light-emitting structures 31, thereby reducing the probability of water and oxygen invading the light-emitting structures 31, and improving the reliability of the light-emitting structures 31.

The first encapsulation layer 40 includes the plurality of encapsulation portions 41, which correspond to the light-emitting structures 31, respectively, to achieve the encapsulation of the light-emitting structures 31. In some embodiments, the plurality of light-emitting structures 31 correspond to the plurality of encapsulation portions 41, respectively, thereby achieving the independent encapsulation of the light-emitting structures 31. Alternatively, one encapsulation portion 41 correspond to the plurality of light-emitting structures 31, and the plurality of light-emitting structures 31 can be encapsulated through the one encapsulation portion 41. For example, the plurality of light-emitting structures 31 with the same color can be encapsulated through the one encapsulation portion 41.

The length of the second portion 22 protruding from the first portion 21 towards the side facing the first opening 23a is L1, which can be understood as, on a cross section along the thickness direction X of the substrate 10 and perpendicular to an extending direction of the isolation structure 20 disposed around a circumferential direction of the first light-emitting structure 31a, a distance between an edge of the second portion 22 on the side facing the first opening 23a and an edge of the first portion 21 on the side facing the first opening 23a parallel to a plane of the substrate 10. The edge of the first portion 21 on the side facing the first opening 23a can refer to an end of the first portion 21 facing the substrate 10 on the side facing the first opening 23a, or an end of the first portion 21 away from the substrate 10 on the side facing the first opening 23a.

The length of the second portion 22 protruding from the first portion 21 towards the side facing the second opening 23b is L2, which can be understood as, on a cross section along the thickness direction X of the substrate 10 and perpendicular to an extending direction of the isolation structure 20 disposed around a circumferential direction of the second light-emitting structure 31b, a distance between an edge of the second portion 22 on the side facing the second opening 23b and an edge of the first portion 21 on the side facing the second opening 23b, in the direction parallel to the plane where the substrate 10 is located. The edge of the first portion 21 on the side facing the second opening 23b can refer to an end of the first portion 21 facing the substrate 10 on the side facing the second opening 23b, or an end of the first portion 21 away from the substrate 10 on the side facing the second opening 23b.

In the display panel provided by the embodiments of the present application, since the thickness D2 of the second light-emitting structure 31b is larger than the thickness D1 of the first light-emitting structure 31a, the isolation structure 20 includes the first portion 21 and the second portion 22 sequentially arranged in the direction away from the substrate 10. The orthographic projection of the first portion 21 on the substrate 10 is located within the orthographic projection of the second portion 22 on the substrate 10. The length of a portion of the second portion 22 protruding from the first portion 21 towards a side facing the first opening 23a is L1, the length of a portion of the second portion 22 protruding from the first portion 21 towards a side facing the second opening 23b is L2, and L1<L2. Thus, during a forming process of the display panel, the light-emitting structures 31 can be formed in an order from thin to thick. During this process, the light-emitting structures 31 with the latter thickness requirement will not cause damage to the encapsulation portions 41 of the formed light-emitting structures 31 with the previous thickness requirement during patterning, so as to reduce the probability of the display failure of parts of light-emitting structures 31 and improve the reliability of the display panel.

Since the orthographic projection of the first portion 21 on the substrate 10 is located within the orthographic projection of the second portion 22 on the substrate 10, the second portion 22 at least partially extends beyond the first portion 21 in a direction parallel to the plane where the substrate 10 is located. According to this design, during the process of manufacturing the light-emitting structures 31, the light-emitting material falling into the openings 23 can be separated from the light-emitting material located on the side of the second portion 22 away from the substrate 10, so as to meet the manufacturing requirement of the light-emitting structures 31.

In some optional embodiments, in the display panel provided by the embodiments of the present application, the plurality of openings 23 further include a third opening 23c, the plurality of light-emitting structures 31 further include a third light-emitting structure 31c arranged in the third opening 23c, a thickness D3 of the third light-emitting structure 31c is larger than the thickness D2 of the second light-emitting structure 31b in the thickness direction X, a length of an edge of the second portion 22 protruding from the first portion 21 towards the third opening 23c is L3, and L2<L3.

There may be a plurality of the third openings 23c, and the number of the third opening 23c can be equal to the number of the first openings 23a and the number of the second openings 23b. Alternatively, there may be differences among them, which can be set according to the arrangement structure of the light-emitting structures 31 with different light colors.

Each of the third openings 23c is provided with the third light-emitting structure 31c. The length of an edge of the second portion 22 protruding from the first portion 21 towards the third opening 23c is L3, which can be understood as, on a cross section along the thickness direction X of the substrate 10 and perpendicular to an extending direction of the isolation structure 20 disposed around a circumferential direction of the third light-emitting structure 31c, a distance between an edge of the second portion 22 on the side facing the third opening 23c and an edge of the first portion 21 on the side facing the third opening 23c, in the direction parallel to the plane where the substrate 10 is located. The edge of the first portion 21 on the side facing the third opening 23c can refer to an end of the first portion 21 facing the substrate 10 on the side facing the third opening 23c, or an end of the first portion 21 away from the substrate 10 on the side facing the third opening 23c.

The color of the light emitted by the third light-emitting structure 31c may be different from each of the color of the light emitted by the first light-emitting structure 31a and the color of the light emitted by the second light-emitting structure 31b.

In the display panel provided by the embodiments of the present application, according to the above arrangement, when the plurality of light-emitting structures 31 of the display panel have three or more thickness specifications, the light-emitting structures 31 can be formed in the order from thin to thick. During this process, the light-emitting structures 31 with the latter thickness requirement will not cause damage to the encapsulation portions 41 of the formed light-emitting structures 31 with the previous thickness requirement during patterning, so as to reduce the probability of the display failure of parts of light-emitting structures 31 and improve the reliability of the display panel.

It can be understood that, in the display panel provided by the embodiments of the present application, two of the colors of the light emitted by the first light-emitting structure 31a, the second light-emitting structure 31b and the third light-emitting structure 31c may be different from another color, or three colors are different from one another, and the colors can be set according to the display requirement.

In some optional embodiments, in the display panel provided by the embodiments of the present application, colors of light emitted by the first light-emitting structure 31a, the second light-emitting structure 31b and the third emitting structure 31c are different from one another.

That is, all the colors of light emitted by the first light-emitting structure 31a, the second light-emitting structure 31b and the third emitting structure 31c are not same as one another.

In the display panel provided by the embodiments of the present application, according to the above arrangement, the diversified display requirement of the display panel can be effectively ensured. In addition, according to the above arrangement, when the display panel is formed, it is beneficial for the display panel to be formed step by step according to the colors. For example, the light-emitting structure 31 with a corresponding light-emitting color and the thinnest thickness can be formed firstly, then the light-emitting structure 31 with a corresponding light-emitting color and a second thin thickness can be formed, and finally, the light-emitting structure 31 with a corresponding light-emitting color and the thickest thickness can be formed, thereby effectively avoiding the damage to the encapsulation portions 41 of the light-emitting structures 31 and improving the reliability of the display panel.

In some optional embodiments, a wavelength of light emitted by the first light-emitting structure 31a is shorter than a wavelength of light emitted by the second light-emitting structure 31b.

In some optional embodiments, the wavelength of the light emitted by the first light-emitting structure 31a is shorter than a wavelength of light emitted by the third light-emitting structure 31c.

In some optional embodiments, the wavelength of the light emitted by the second light-emitting structure 31b is shorter than the wavelength of the light emitted by the third light-emitting structure 31c.

According to the above arrangement, the diversified display requirement of the display panel can be effectively ensured. In addition, according to the above arrangement, when the display panel is formed, it is beneficial for the display panel to be formed step by step according to the colors. For example, the light-emitting structure 31 with a corresponding light-emitting color and the shortest wavelength can be formed firstly, then the light-emitting structure 31 with a corresponding light-emitting color and a relatively longer wavelength can be formed, and finally, the light-emitting structure 31 with a corresponding light-emitting color and the longest wavelength can be formed, thereby effectively avoiding the damage to the encapsulation portions 41 of the light-emitting structures 31 and improving the reliability of the display panel.

In some optional embodiments, in the display panel provided by the embodiments of present application, the light emitted by the first light-emitting structure 31a includes blue light, the light emitted by the second light-emitting structure 31b includes green light, and the light emitted by the third light-emitting structure 31c includes red light.

According to the above arrangement, the display requirement of the display panel can be effectively ensured. In addition, based on the characteristics of the light-emitting materials with different light-emitting colors and the brightness requirements of the display panel for the light-emitting structures 31 with different colors, a thickness of the light-emitting structure 31 emitting the blue light is smaller than a thickness of the light-emitting structure 31 emitting the green light, and the thickness of the light-emitting structure 31 emitting the green light is smaller than a thickness of the light-emitting structure emitting the red light. Therefore, according to the above arrangement, on the basis of meeting the display requirement, the light-emitting structures 31 of the display panel are formed in the order from thin to thick during the forming process, so as to avoid the display failure of the light-emitting structures 31 formed previously during the forming process.

In some optional embodiments, each of a light-emitting area of the first light-emitting structure 31a and a light-emitting area of the third light-emitting structure 31c is larger than a light-emitting area of the second light-emitting structure 31b, and/or the light-emitting area of the third light-emitting structure 31c is smaller than the light-emitting area of the first light-emitting structure 31a.

The light-emitting area can be understood as the light-emitting area corresponding to the light-emitting structures 31 within the openings 23.

In some optional embodiments, in the display panel provided by the above embodiments of the present application, the encapsulation portions 41 are in contact with a side wall of the first portion 21 facing the openings 23 and extends to a side of the second portion 22 away from the substrate 10 along the side wall. According to the above arrangement, the protective effect of the light-emitting structures 31 can be ensured and it facilitate the formation of the light-emitting structures 31 with different colors.

In some optional embodiments, the plurality of encapsulation portions 41 include a first encapsulation portion 41a located on a side of the first light-emitting structure 31a away from the substrate 10, and a second encapsulation portion 41b located on a side of the second light-emitting structure 31b away from the substrate 10. At least a portion of the first encapsulation portion 41a is spaced apart from and opposite to a surface of the second portion 22 away from the first portion 21 in the thickness direction X to form a first gap 91, and a size of the first gap 91 in the thickness direction X is smaller than the thickness of the second light-emitting structure 31b.

In some optional embodiments, at least a portion of the second encapsulation portion 41b is spaced apart from and opposite to the surface of the second portion 22 away from the first portion 21 to form a second gap 92.

In some optional embodiments, the size d1 of the first gap 91 in the thickness direction X is smaller than a size d2 of the second gap 92 in the thickness direction X.

In some optional embodiments, the size of the first gap 91 in the thickness direction X is larger than or equal to the thickness of the first light-emitting structure 31a. In some embodiments, another function layer, such as a light extraction layer, is arranged between the light-emitting structures 31 and the encapsulation portions 41. The size of the first gap 91 in the thickness direction X is larger than the thickness of the first light-emitting structure 31a.

A portion of the first encapsulation portion 41a is located inside the first opening 23a and protects the first light-emitting structure 31a. A portion of the first encapsulation portion 41a is attached to a wall of the isolation structure 20 facing the first opening 23a, and at least partially climbs up to a side of the isolation structure 20 away from the substrate 10 in the thickness direction X. The first gap 91 is formed between the portion of the first encapsulation portion 41a and the surface of the second portion 22 away from the first portion 21.

A portion of the second encapsulation portion 41b is located inside the second opening 23b and protects the second light-emitting structure 31b. A portion of the second encapsulation portion 41b is attached to the wall of the isolation structure 20 facing the second opening 23b, and at least partially climbs up to a side of the isolation structure 20 away from the substrate 10 in the thickness direction X. The second gap 92 is formed between the portion of the second encapsulation portion 41b and the surface of the second portion 22 away from the first portion 21.

In the display panel provided by the embodiments of the present application, the first gap 91 and the second gap 92 are formed by etching a light-emitting material layer, which forms the light-emitting structures 31, located between a surface of the second portion 22 on the side away from the first portion 21 and the first encapsulation layer 40 during the forming process of the display panel. The size d1 of the first gap 91 is smaller than the thickness of the second light-emitting structure 31b, that is, the size d1 of the first gap 91 is smaller than the size d2 of the second gap 92, thereby avoiding the display failure of the light-emitting structures 31 formed previously during the forming process. In addition, it can ensure that the thickness of the first light-emitting structure 31a formed in the first opening 23a is smaller than the thickness of the second light-emitting structure 31b formed in the second opening 23b, and the light-emitting structures 31 can be formed in the order from thin to thick.

In some optional embodiments, in the display panel provided by an embodiment of the present application, the size of the first gap 91 in the thickness direction X is smaller than the thickness of the second light-emitting structure 31b. During the forming process of the second light-emitting structure 31b, the edge of the first encapsulation portion 41a can be arranged continuously, so as to protect the first encapsulation portion 41a.

In some optional embodiments, in the display panel provided by an embodiment of the present application, an orthographic projection of the first encapsulation portion 41a on the substrate 10 is spaced apart from an orthographic projection of the second encapsulation portion 41b on the substrate 10, so as to facilitate the forming of the first encapsulation portion 41a and the second encapsulation portion 41b in step-by-step.

In some optional embodiments, in the display panel provided by an embodiment of the present application, the plurality of openings 23 further include a third opening 23c, and the plurality of light-emitting structures 31 further include a third light-emitting structure 31c arranged in the third opening 23c. A thickness of the third light-emitting structure 31c is larger than the thickness of the second light-emitting structure 31b in the thickness direction X, a length of an edge of the second portion 22 protruding from the first portion 21 towards the third opening 23c is L3, and L2<L3. In this case, the plurality of encapsulation portions 41 further include a third encapsulation portion 41c located on a side of the third light-emitting structure 31c away from the substrate 10, and at least a portion of the third encapsulation portion 41c is spaced apart from and opposite to the surface of the second portion 22 away from the first portion 21 to form a third gap 93. A size d2 of the second gap 92 is smaller than s thickness of the third gap 93, that is, the size d2 of the second gap 92 is smaller than a size d3 of the third gap 93, so as to avoid the display failure of the previously formed light-emitting structure 31 during the forming process.

A portion of the third encapsulation portion 41c is located inside the third opening 23c and protects the third light-emitting structure 31c. A portion of the third encapsulation portion 41c is attached to the wall of the isolation structure 20 facing the third opening 23c, and at least partially climbs up to the side of the isolation structure 20 away from the substrate 10 in the thickness direction X. The third gap 93 is formed between the portion of the third encapsulation portion 41c and the surface of the second portion 22 away from the first portion 21.

In the display panel provided by the embodiments of the present application, the third gap 93 is also formed by etching a light-emitting material layer, which forms the light-emitting structures 31, located between a surface of the second portion 22 on the side away from the first portion 21 and the encapsulation portions 41 during the forming process of the display panel. The size d2 of the second gap 92 is smaller than the size d3 of the third gap 93, so that it can be ensured that the thickness of the second light-emitting structure 31b formed in the second opening 23b is smaller than the thickness of the third light-emitting structure 31c formed in the third opening 23c, and the light-emitting structures 31 can be formed in the order from thin to thick.

In some optional embodiments, in the thickness direction X, the size d1 of the first gap 91 is equal to the thickness D1 of the first light-emitting structure 31a, the size d2 of the second gap 92 is equal to the thickness D2 of the second light-emitting structure 31b, and the size d3 of the third gap 93 is equal to the thickness D3 of the third light-emitting structure 31c.

According to the above arrangement, the display panel provided by the embodiments of the present application can ensure that all the light-emitting material layers formed within the first gap 91, second gap 92 and third gap 93 for forming the light-emitting structures 31 can be etched off, ensure the forming quality and display effect of the display panel, and improve the reliability of the display panel.

In some optional embodiments, the size of the second gap 92 in the thickness direction X. According to the above arrangement, it is beneficial to forming the light-emitting structures 31 in the order from thin to thick, so as to avoid the display failure of the previously formed light-emitting structure 31 during the forming process.

Optionally, the size of the first gap 91 in the thickness direction X is larger than or equal to the thickness of the first light-emitting structure 31a. In some embodiments, there is another function layer, such as a light extraction layer, between the light-emitting structures 31 and the encapsulation portions 41. The size of the first gap 91 in the thickness direction X is larger than the thickness of the first light-emitting structure 31a.

Optionally, the size of the second gap 92 in the thickness direction X is larger than or equal to the thickness of the second light-emitting structure 31b. In some embodiments, there is another function layer, such as a light extraction layer, between the light-emitting structures 31 and the encapsulation portions 41. The size of the second gap 92 in the thickness direction X is larger than the thickness of the second light-emitting structure 31b.

Optionally, the size of the third gap 93 in the thickness direction X is larger than or equal to the thickness of the third light-emitting structure 31c. In some embodiments, there is another function layer, such as a light extraction layer, between the light-emitting structures 31 and the encapsulation portions 41. The size of the third gap 93 in the thickness direction X is larger than the thickness of the second light-emitting structure 31c.

In some optional embodiments, in the thickness direction X, the sum of the size of the first gap 91 and the thickness value of the first encapsulation portion 41a is less than the thickness of the second light-emitting structure 31b. The thickness of the first encapsulation portion 41a can refer to the thickness of the first encapsulation portion 41a extending to the side of the second portion 22 away from the substrate 10.

Optionally, in the thickness direction X, the sum of the size of the second gap 92 and the thickness value of the second encapsulation portion 41b is less than the thickness of the third light-emitting structure 31c. The thickness of the second encapsulation portion 41b can refer to the thickness of the second encapsulation portion 41b extending to the side of the second portion 22 away from the substrate 10.

According to the arrangement, the display panel provided by an embodiment of the present application facilitates forming the light-emitting structures 31 in the order from thin to thick. During this process, the light-emitting structures 31 with the latter thickness requirement will not cause damage to the encapsulation portions 41 of the formed light-emitting structures 31 with the previous thickness requirement during patterning, so as to reduce the probability of the display failure of parts of light-emitting structures 31 and improve the reliability of the display panel.

In some optional embodiments, the display panel provided by an embodiment of the present application, the first encapsulation layer 40 includes the inorganic material.

The inorganic material may be the material such as silicon nitride, silicon oxide and silicon oxynitride, which can be formed by the Chemical Vapor Deposition (CVD) process.

According the above arrangement, water and oxygen can be blocked effectively, the protecting effect on the light-emitting structures 31 can be ensured.

As shown in FIG. 6, in some optional embodiments, the display panel provided by the embodiments of present application further includes a second encapsulation layer 50, which is arranged on the side of the first encapsulation layer 40 away from the substrate 10, and the second encapsulation layer 50 covers the plurality of encapsulation portions 41.

The first encapsulation layer 40 and the second encapsulation layer 50 are jointly used to achieve the encapsulation effect of the display panel, and the second encapsulation layer 50 is located on the side of the first encapsulation layer 40 away from the substrate 10. From the above content, it can be seen that the light-emitting structures 31 with different thicknesses may cause a non-flat surface on the side of the first encapsulation layer 40 away from the substrate 10, which can lead to an adverse effect on an upper film layer.

In view of this, in the manufacturing process in the embodiments of the present application, the size and shape of the second encapsulation layer 50 can be controlled, so that the second encapsulation layer 50 is provided as a whole surface structure, and the surface of the second encapsulation layer 50 on the side away from the substrate 10 can be parallel or substantially parallel to the plane where the substrate 10 is located, thereby reducing the impact on the subsequent manufacturing process for the film layer.

In some optional embodiments, the display panel provided by the embodiments of the present application, at least a portion of the second encapsulation layer 50 is filled in the first gap 91, the second gap 92 and the third gap 93, so that the strength and stability of the encapsulation structures can be ensured, and the protecting effect on the light-emitting structures 31 can be ensured.

In some optional embodiments, the display panel provided by the embodiments of the present application, the second encapsulation layer 50 includes an organic material. Generally, the organic material has a strong levelling property, so that it is conducive to achieving a flat surface on the side of the second encapsulation layer 50 away from the substrate 10 when the second encapsulation layer 50 is formed.

In some embodiments, the display panel further includes a third encapsulation layer 60 located on a side of the second encapsulation layer 50 away from the substrate 10. The third encapsulation layer 60 is arranged on the side of the second encapsulation layer 50 away from the substrate 10, and the orthographic projection of the third encapsulation layer 60 on the substrate 10 can cover the orthographic projection of the plurality of encapsulation portions 41 on the substrate 10.

Similar with the second encapsulation layer 50, the third encapsulation layer 60 can also be a whole surface structure and can cover the plurality of encapsulation portions 41. Herein, the first encapsulation layer 40, the second encapsulation layer 50 and the third encapsulation layer 60 can jointly form a thin film encapsulation structure, so as to improve the encapsulation effect of the display panel.

Optionally, the third encapsulation layer 60 includes the inorganic material, which can effectively enhance the protecting effect on the light-emitting structures 31.

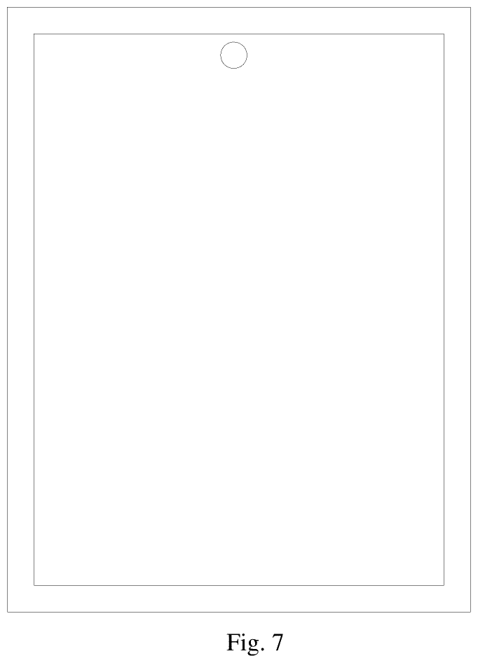

As shown in FIG. 7, in some optional embodiments, in the display panel provided by an embodiment of the present application, on a cross section along the thickness direction X of the substrate 10 and perpendicular to an extending direction of the isolation structure 20 disposed around a circumferential direction of the first light-emitting structure 31a, a distance between an edge of the isolation structure 20 located in the circumferential direction of the first light-emitting structure 31a and an edge of an end of the first encapsulation portion 41a, in a direction parallel to the plane where the substrate 10 is located, is M1, on a cross section along the thickness direction X of the substrate 10 and perpendicular to an extending direction of the isolation structure 20 disposed around a circumferential direction of the second light-emitting structure 31b, a distance between an edge of the isolation structure 20 located in the circumferential direction of the second light-emitting structure 31b and an edge of the second encapsulation portion 31b, in the direction parallel to the plane where the substrate 10 is located, is M2, and M1<M2.

Optionally, the plurality of openings 23 further includes a third opening 23c, the plurality of light-emitting structures 31 further include a third light-emitting structure 31c arranged in the third opening 23c, and a thickness of the third light-emitting structure 31c is larger than the thickness of the second light-emitting structure 31b in the thickness direction X. The plurality of encapsulation portions 41 further include a third encapsulation portion 41c located on a side of the third light-emitting structure 31c away from the substrate 10. On a cross section along the thickness direction X of the substrate 10 and perpendicular to an extending direction of the isolation structure 20 disposed around a circumferential direction of the third light-emitting structure 31c, a distance between an edge of the isolation structure 20 located in the circumferential direction of the third light-emitting structure 31c and an edge of the third encapsulation portion 41c, in the direction parallel to the plane where the substrate 10 is located is M3, and M2<M3.

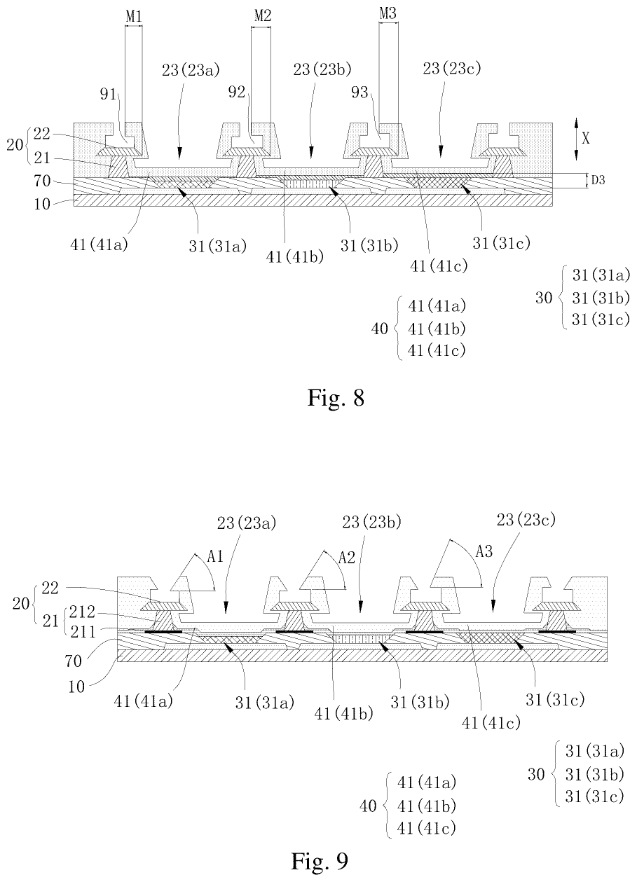

As shown in FIG. 8, in some optional embodiments, in the display panel provided by an embodiment of the present application, an end of the first encapsulation portion 41a is provided with a first surface, an end of the second encapsulation portion 41b is provided with a second surface. On the cross section along the thickness direction X of the substrate 10 and perpendicular to the extending direction of the isolation structure 20 disposed around a circumferential direction of the first light-emitting structure 31a, an inclination angle between the first surface and a plane where the substrate 10 is located is A1; and on the cross section along the thickness direction X of the substrate 10 and perpendicular to the extending direction of the isolation structure 20 disposed around a circumferential direction of the second light-emitting structure 31b, an inclination angle between the second surface and the plane where the substrate 10 is located is A1; and A1<A2. The inclination angle in the present application refers to an angle between two surfaces (planes).

Obviously, the plurality of openings 23 further include a third opening 23c, the plurality of light-emitting structures 31 further include a third light-emitting structure 31c arranged in the third opening 23c, and a thickness of the third light-emitting structure 31c is larger than the thickness of the second light-emitting structure 31b in the thickness direction X. The plurality of encapsulation portions 41 further include a third encapsulation portion 41c located on a side of the third light-emitting structure 31c away from the substrate 10, an end of the third encapsulation portion 41c is provided with a third surface, on a cross section along the thickness direction X of the substrate 10 and perpendicular to an extending direction of the isolation structure 20 disposed around a circumferential direction of the third light-emitting structure 31c, an inclination angle between the third surface and the plane where the substrate 10 is located is A3, and A2<A3.

In some optional embodiments, in the display panel provided by an embodiment of the present application, the light-emitting structures 31 include an organic material layer 311 and a first electrode 312 located on a side of the organic material layer 311 away from the substrate 10. The material of the isolation structure 20 includes a metal material, and the first electrode 312 is in contact with and connected to the isolation structure 20.

The organic material layer 311 may include a hole injection layer (HIL), a hole transport layer (HTL), a light-emitting layer, an electron inject layer (EIL) and an electron transport layer (ETL) which are stacked.

The material of the first electrode 312 may be one of the metal materials such as silver (Ag), aluminum (Al), lithium (Li), magnesium (Mg), ytterbium (Yb), calcium (Ca) or indium (In), or may be an alloy of the metal materials mentioned above, such as magnesium silver alloy (Mg/Ag) or lithium aluminum alloy (Li/Al). This embodiment is not limited to this.

Since the isolation structure 20 is formed, the plurality of first electrodes 312 can be formed by direct evaporation or other methods without the need for a fine metal mask plate, so that the cost of mask for manufacturing the display panel can be reduced and the method is suitable for a large-scale production.

On this basis, in order to enable at least parts of the first electrodes 312 to obtain the corresponding potential signals, the first electrodes 312 are in contact with and connected to the isolation structure 20. According to this design, the first electrode 312 is electrically connected to the first portion 21, so that the driving control for the first electrode 312 can be achieved through the first portion 21 transmitting a specific potential signal to the first electrodes 312.

In some optional embodiments, the display panel provided by the embodiments of the present application further includes a second electrode 80, which is located between the substrate 10 and the light-emitting function layer 30. The first electrode 312 may be a cathode, and the second electrode 80 may be an anode. The first electrode 312 and the second electrode 80 jointly drive the light-emitting structures 31 to achieve the light-emitting display.

Generally, the material of the second electrode 80 may be a material with a high work function, so as to improve the efficiency of the hole injection. The material may be gold (Au), platinum (Pt), titanium (Ti), silver (Ag), indium tin oxide (ITO), zinc tin oxide (IZO), transparent conductive polymer (such as polyaniline) or the like. For example, the second electrode 80 may be made of ITO-Ag-ITO composite material, which is not specially limited.

In some optional embodiments, in the display panel provided by an embodiment of the present application, a thickness of the organic material layer 311 of the second light-emitting structure 31b in the display panel is larger than a thickness of the organic material layer 311 of the first light-emitting structure 31a. In some embodiments, a thickness of the first electrode 312 of the first light-emitting structure 31a is smaller than a thickness of the first electrode 312 of the second light-emitting structure 31b. Thus, it is conducive that the film layers are continuous at an edge of the encapsulation portion when the film layers of the later formed light-emitting structure are evaporated, thereby protecting the previously formed light-emitting structures and improving the product yield.

Optionally, the openings 23 further include a third opening 23c, and the light-emitting structures 31 further include a third light-emitting structure 31c located in the third opening 23c. A thickness of the organic material layer 311 of the third light-emitting structure 31c is larger than the thickness of the organic material layer 311 of the second light-emitting structure 31b.

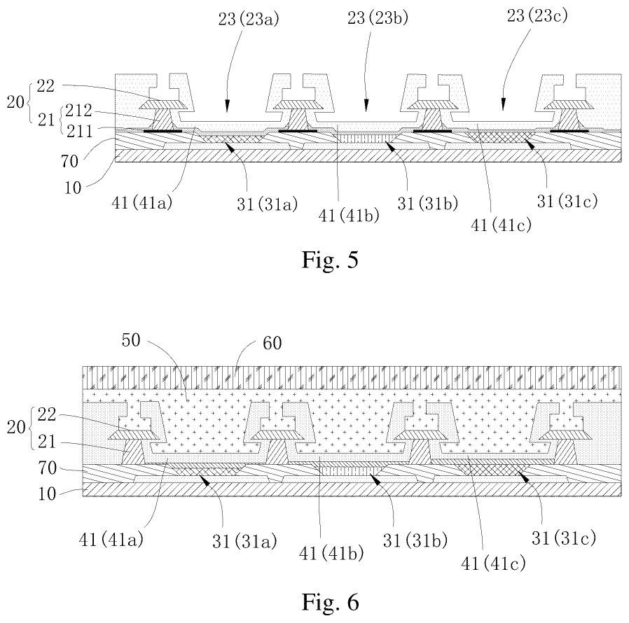

As shown in FIG. 5, in some optional embodiments, the first portion 21 includes a first sub-layer 211 and a second sub-layer 212 sequentially arranged in the direction away from the substrate 10, the first sub-layer 211 protrudes from the second sub-layer 212 towards a side facing the openings 23, and the first electrode 312 is in contact with and connected to at least one of the first sub-layer 211 and the second sub-layer 212.

The first electrode 312 may be in contact with and connected to the first sub-layer 211. Alternatively, the first electrode 312 may be in contact with and connected to the first sub-layer 211 and the second sub-layer 212 synchronously.

As shown in FIG. 9, in a second aspect, embodiments of the present application provide a display device including the display panel according to any one of the embodiments as described above.

The flexible display device provided by the embodiments of the present application has the beneficial effects of the display panel according to any one of the embodiments as described above. The specific content is detailed in the description of the beneficial effects of the display panel, and will not be repeated in the embodiments of the present application.

In a third aspect, as shown in FIG. 10 to FIG. 17, the embodiments of the present application provide a method of manufacturing the display panel, which can be used to form the display panel provided by the embodiments as described above. The method includes:
S100: forming an isolation structure 20 on a side of a substrate 10 in a thickness direction X thereof, the isolation structure 20 surrounding and forming a plurality of openings 23, and the plurality of openings 23 including a first opening 23a and a second opening 23b;
S200: forming a first encapsulation material layer 120 and a first light-emitting structural layer 110 with a first thickness on the substrate 10 and the isolation structure 20;
S300: removing at least a portion of the first encapsulation material layer 120 and a portion of the first light-emitting structural layer 110 outside the first opening 23a to form the first light-emitting structure 31a located within the first opening 23a and a first encapsulation portion 41a covering the first light-emitting structure 31a;
S400: forming a second encapsulation material layer and a second light-emitting structural layer with a second thickness on the substrate 10 and the isolation structure 20, and the second thickness being larger than the first thickness; and
S500: removing at least a portion of the second encapsulation material layer and a portion of the second light-emitting structural layer outside the second opening 23b to form the second light-emitting structure 31b located within the second opening 23b and a second encapsulation portion 41b covering the second light-emitting structure 31b.

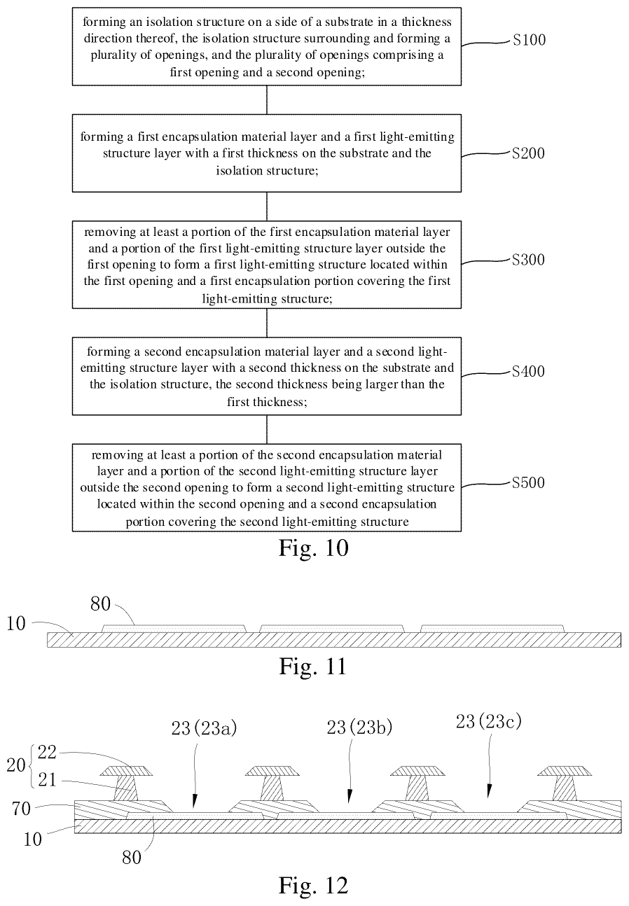

As shown in FIG. 11 and FIG. 12, in step S100, a pixel-limiting layer 70 and a plurality of second electrodes 80 are formed on the substrate 10, or a pixel-limiting layer 70 and the plurality of second electrodes 80 are previously formed on the substrate 10 before step S100. The isolation structure 20 surrounds and forms the plurality of openings 23. The specific structure of the isolation structure 20 can refer to the structure of the display panel provided by the embodiments described above. Two layers of isolation layers can be sequentially formed when the isolation structure 20 is formed, and then the isolation layers are patterned to form the patterned isolation structure 20. The formed isolation structure 20 includes the first portion 21 and the second portion 22 arranged in sequence in a direction away from the substrate 10. An orthographic projection of the first portion 21 on the substrate 10 is located within an orthographic projection of the second portion 22 on the substrate 10.

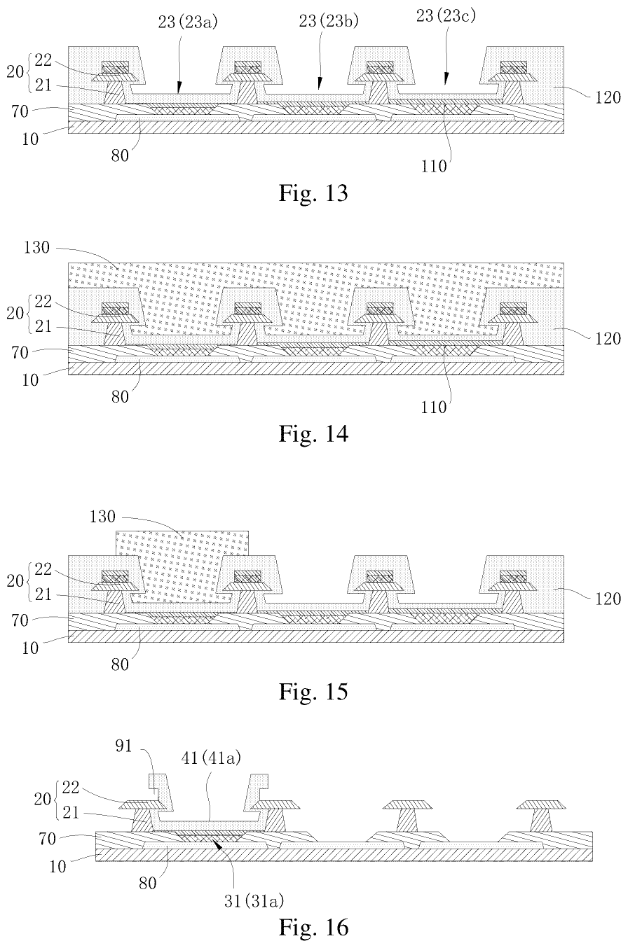

As shown in FIG. 13, in step S200, the first light-emitting structural layer 110 can be formed on the substrate 10 and the isolation structure 20 by means of direct evaporation or other methods. Due to the structure of the isolation structure 20, a portion of the first light-emitting structural layer 110 falls to the openings 23, another portion of the first light-emitting structural layer falls to a side wall of the isolation structure 20 and climbs up to a side of the isolation structure 20 away from the substrate 10, and the first encapsulation material layer 120 is formed on the first light-emitting structural layer.

The first light-emitting structural layer 110 may include a multi-layer structure, which may optionally include a first light-emitting material layer forming an organic material layer 311 and a first electrode material layer forming a first electrode 312.

Exemplarily, the first light-emitting structural layer 110 may include an organic material capable of emitting blue light.

As shown in FIG. 14 to FIG. 16, in step S300, a colloid 130 can be arranged, and a portion of the colloid 130 can be removed by exposure, development or other processes. As shown in FIG. 15, a portion of colloid 130 at the first opening 23a and around the first opening 23a is retained, and the retained colloid 130 can be used as a mask plate to etch and remove a portion of the first light-emitting structural layer 110 outside the first opening and at least a portion of the first encapsulation material layer 120, so as to form the first light-emitting structure 31a located within the first opening 23a and the first encapsulation portion 41a covering the first light-emitting structure 31a. Moreover, a portion of the first light-emitting structural layer 110 outside the first opening is removed, so that at least a portion of the first encapsulation portion 41a is spaced apart from the surface of the second portion 22 of the isolation structure 20 away from the first portion 21 to form a first gap 91.

In step S400, the second light-emitting structural layer can also be formed on the substrate 10 and the isolation structure 20 by means of the direct evaporation or other methods. Due to the structure of the isolation structure 20, the second light-emitting structural layer is disconnected at the isolation structure 20, a portion of the second light-emitting structural layer falls to the openings 23, another portion of the second light-emitting structural layer falls on the side wall of the isolation structure 20 and climbs up to the side of the isolation structure 20 away from the substrate 10, and the second encapsulation material layer is formed on the second light-emitting structural layer.

The second light-emitting structural layer may include a multi-layer structure, which may optionally include a second light-emitting material layer forming the organic material layer 311 and the first electrode material layer forming the first electrode 312.

Exemplarily, the second light-emitting structural layer may include an organic material capable of emitting green light.

A material of the second encapsulation material layer may be the same as a material of the first encapsulation material layer 120.

Since a thickness of the second light-emitting structural layer is larger than a thickness of the first light-emitting structural layer 110, correspondingly, the thickness of the second light-emitting structural layer is also larger than a size of the first gap 91, that is, the size of the first gap 91 is smaller than the thickness of the second light-emitting structure 31b. When the second light-emitting structural layer is formed, the organic material layer 311 of the second light-emitting structural layer can fully fill the first gap 91 and the opening 23, so that the organic material layer can continuously cover a boundary of the first gap 91, and the first electrode material can be continuous between the openings 23 and the first gap 91. Thus, during the process of patterning to form the second light-emitting structure 31b, the previously formed first encapsulation portion 41a can be protected, so as to prevent from the failure of the first light-emitting structure 31a.

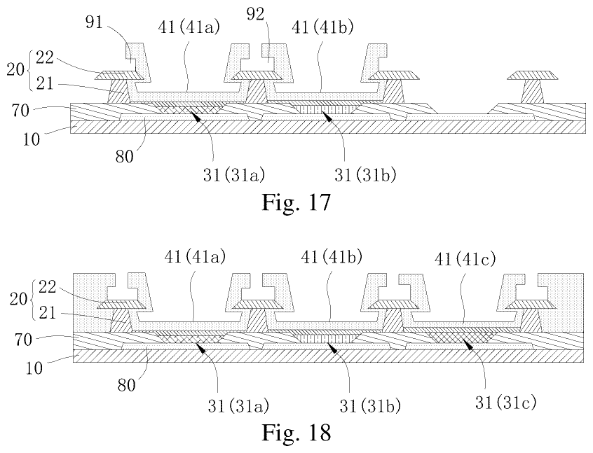

As shown in FIG. 17, in step S500, a portion of the second light-emitting structural layer outside the second opening 23b and at least a portion of the second encapsulation material layer can be removed by exposure, development or other processes to form the second light-emitting structure 31b located within the second opening 23b and the second encapsulation portion 41b covering the second light-emitting structure 31b.

Since the second light-emitting structure 31b is formed later than the first light-emitting structure 31a, a length of a portion of the second portion 22 protruding from the first portion 21 towards the first opening 23a and a length of another portion of the second portion 22 protruding from the first portion 21 towards the second opening 23b are different under the previous operation such as exposure, development or etching. Specifically, the length of a portion of the second portion 22 of the display panel protruding from the first portion 21 towards the first opening 23a is L1, the length of another portion of the second portion 22 of the display panel protruding from the first portion 21 towards the second opening 23b is L2, and L1<L2.

The method of manufacturing the display panel provided by the embodiments of the present application can be used to form the display panel provided by the embodiments as described above. The method provided by the embodiments of the present application may include the direct evaporation or other methods to form the light-emitting structures 31 and the encapsulation portions 41, which can reduce the cost of mask for manufacturing the display panel and be suitable for the large-scale production. The first light-emitting structure 31a with a light color and the first encapsulation portion 41a can be formed at a region corresponding to the first opening 23a firstly, then the second light-emitting structure 31n with another light color and the second encapsulation portion 41b can be formed at a region corresponding to the second opening 23b. Since the thickness of the first light-emitting structural layer 110 used for forming the first light-emitting structure 31a is smaller than the thickness of the second light-emitting structural layer used for forming the second light-emitting structure 31b, that is, the thickness of the first gap 91 is smaller than the thickness of the second light-emitting structural layer, the second light-emitting structural layer can fully fill the first gap 91 between the first encapsulation portion 41b and the isolation structure 20 when the first electrode material layer and the second encapsulation material layer is formed on the second light-emitting structural layer. Thus, there will be no segment difference between the first electrode material layer and the second encapsulation material layer, and the first electrode material layer can wrap and cover the first encapsulation portion 41a. During the process of removing a portion of the second encapsulation material layer through etching or other processes to form the second encapsulation portion 41b, the first electrode material layer can protect the first encapsulation portion 41a and prevent from the etching damage to the first encapsulation portion 41a, reduce the failure probability of the light-emitting structures 31 of the formed display panel, and improve the reliability of the formed display panel.

Optionally, according to removing the second light-emitting structural layer, at least a portion of the second encapsulation portion 41b is spaced apart from and opposite to the surface of the second portion 22 of the isolation structure 20 away from the first portion 21 to form a second gap 92.

In some optional embodiments, in the step of forming the second encapsulation material layer and the second light-emitting structural layer with the second thickness on the substrate 10 and the isolation structure 20, the second light-emitting structural layer is continuously arranged at an edge of the first encapsulation portion 41a.

As shown in FIG. 18, when the plurality of openings 23 include a third opening 23c, the method may further include forming a third encapsulation material layer and a third light-emitting structural layer with a third thickness on the substrate 10 and the isolation structure 20, and the third thickness being larger than the second thickness; and removing at least a portion of the third encapsulation material layer and a portion of the third light-emitting structural layer outside the third opening 23c to form a third light-emitting structure 31c located within the third opening 23c and a third encapsulation portion 41c covering the third light-emitting structure 31c.

The third light-emitting structural layer can also be formed on the substrate 10 and the isolation structure 20 by means of the direct evaporation or other methods, and the third encapsulation material layer can be formed on the third light-emitting structural layer. Due to the structure of the isolation structure 20, the third light-emitting structural layer is disconnected at the isolation structure 20, a portion of the third light-emitting structural layer falls to the openings 23, and another portion of the third light-emitting structural layer falls on the side wall of the isolation structure 20 and climbs up to the side of the isolation structure 20 away from the substrate 10.

The third light-emitting structural layer may be a multi-layer structure, and may optionally include a third light-emitting material layer forming the organic material layer 311 and a metal layer forming the first electrode 312.

Exemplarily, the third light-emitting structural layer may include the organic material capable of emitting green light.

A material of the third encapsulation material layer may be the same as the material of the first encapsulation material layer 120.

Since a thickness of the third light-emitting structural layer is larger than the thickness of the second light-emitting structural layer, correspondingly, the thickness of the third light-emitting structural layer is also larger than a size of the second gap 92, that is, the size of the second gap 92 is smaller than the thickness of the third light-emitting structure 31c. When the third light-emitting structural layer is formed, the organic material layer 311 of the third light-emitting structural layer can fully fill the second gap 92 and the first gap 91, so that the organic material layer can continuously cover the boundaries of the first gap 91 and the second gap 92, and the first electrode material can be continuous between the first gap 91 and the second gap 92. Thus, during the process of patterning to form the third light-emitting structure 31c, the previously formed first encapsulation portion 41a and the second encapsulation portion 41b can be protected, so as to prevent from the failure of the first light-emitting structure 31a and the second light-emitting structure 31b.

In the step of removing at least a portion of the third encapsulation material layer and a portion of the third light-emitting structural layer outside the third opening 23c, at least a portion of the third encapsulation material layer and a portion of the third light-emitting structural layer outside the third opening 23c can be removed by exposure, development or other processes to form the third light-emitting structure 31c located within the third opening 23c and the third encapsulation portion 41c covering the third light-emitting structure 31c.

Since the third light-emitting structure 31c is formed later than the second light-emitting structure 31b, the length of the portion of the second portion 22 protruding from the first portion 21 towards the second opening 23b and a length of another portion of the second portion 22 protruding from the first portion 21 towards the third opening 23c are different under the previous operation such as exposure. Specifically, the length of a portion of the second portion 22 of the display panel protruding from the first portion 21 towards the third opening 23c is L3, and L2<L3. The thickness of the first light-emitting structure 31a of the formed display panel is less than the thickness of the second light-emitting structure 31b, and the thickness of the second light-emitting structure 31b is less than the thickness of the third light-emitting structure 31c.

As shown in FIG. 1 to FIG. 8, embodiments of the present application further provide a display panel including a substrate 10, an isolation structure 20, a light-emitting function layer 30 and a first encapsulation layer 40. The isolation structure 20 is arranged on a side of the substrate 10 in a thickness direction X thereof, the isolation structure 20 surrounds and forms a plurality of openings 23, and the plurality of openings 23 include a first opening 23a and a second opening 23b. The isolation structure 20 includes the first portion 21 and the second portion 22 sequentially arranged in the direction away from the substrate 10. An orthographic projection of the first portion 21 on the substrate 10 is located within an orthographic projection of the second portion 22 on the substrate 10. The light-emitting function layer 30 is arranged on the substrate 10, the light-emitting function layer 30 includes a plurality of light-emitting structures 31, the plurality of light-emitting structures 31 include a first light-emitting structure 31a arranged in the first opening 23a and a second light-emitting structure 31b arranged in the second opening 23b, and a thickness D2 of the second light-emitting structure 31b is larger than a thickness D1 of the first light-emitting structure 31a in the thickness direction X. The first encapsulation layer 40 includes a plurality of encapsulation portions 41 corresponding to the light-emitting structures 31, respectively. The encapsulation portions 41 are located on a side of the light-emitting structures 31 away from the substrate 10. The plurality of encapsulation portions 41 include a first encapsulation portion 41a located on a side of the first light-emitting structure 31a away from the substrate 10 and a second encapsulation portion 41b located on a side of the second light-emitting structure 31b away from the substrate 10. In the thickness direction X, at least a portion of the first encapsulation portion 41a is spaced apart from and opposite to a surface of the second portion 22 away from the first portion 21 to form a first gap 91, at least a portion of the second encapsulation portion 41b is spaced apart from and opposite to the surface of the second portion 22 away from the first portion 21 to form a second gap 92, and a size of the first gap 91 is smaller than a size of the second gap 92.

The plurality of encapsulation portions 41 can be spaced apart from one another, that is, there are gaps among the plurality of encapsulation portions 41.

In the display panel provided by an embodiment of the present application, the number of openings 23 can be set according to the display requirement of the display panel. There are a plurality of first openings 23a and a plurality of second openings 23b. The number of first openings 23a may be equal to the number of second openings 23b. Alternatively, the number of first openings 23a may be more than or less than the number of the second openings 23b.

The light emitted by the first light-emitting structure 31a and the light emitted by the second light-emitting structure 31b may be different, for example: the light emitted by the first light-emitting structure 31a may include blue light, and the light emitted by the second light-emitting structure 31b may include green light; or the light emitted by the first light-emitting structure 31a may include green light, and the light emitted by the second light-emitting structure 31b may include red light.

The isolation structure 20 can be located on a pixel-limiting layer 70, or on a flattening layer. The position of the isolation structure 20 is not specifically limited here.

Optionally, the isolation structure 20 and the light-emitting function layer 30 are located on the same side of the substrate 10, and the isolation structure 20 surrounds and forms the plurality of openings 23. A size and a shape of the isolation structure 20 are not limited by the embodiments of the present application. Optionally, an orthogonal projection of the isolation structure 20 on the substrate 10 may be a mesh-like structure. Alternatively, in some embodiments, the orthogonal projection of the isolation structure 20 on the substrate 10 may be a plurality of independent circular structures, each of which is provided with the opening 23. All types of the isolation structure 20 mentioned above can meet the usage requirement of the display panel.

The plurality of openings 23 surrounded and formed by the isolation structure 20 can correspond to the light-emitting structures 31 respectively, that is, one light-emitting structure 31 is located within each of openings 23. Alternatively, the plurality of light-emitting structures 31 can be arranged within one opening 23, for example, the plurality of light-emitting structures 31 with the same color can be arranged within one opening 23.

The first encapsulation layer 40 can be used to protect the light-emitting structures 31, thereby reducing the probability of water and oxygen invading the light-emitting structures 31, and improving the reliability of the light-emitting structures 31.

The first encapsulation layer 40 includes the plurality of encapsulation portions 41, which correspond to the light-emitting structures 31, respectively, to achieve the encapsulation of the light-emitting structures 31. In some embodiments, the plurality of light-emitting structures 31 correspond to the plurality of encapsulation portions 41, respectively, thereby achieving the independent encapsulation of the light-emitting structures 31. Alternatively, one encapsulation portion 41 correspond to the plurality of light-emitting structures 31, and the plurality of light-emitting structures 31 can be encapsulated through the one encapsulation portion 41. For example, the plurality of light-emitting structures 31 with the same color can be encapsulated through the one encapsulation portion 41.

A portion of the first encapsulation portion 41a is located inside the first opening 23a and protects the first light-emitting structure 31a. A portion of the first encapsulation portion 41a is attached to a wall of the isolation structure 20 facing the first opening 23a, and at least partially climbs up to a side of the isolation structure 20 away from the substrate 10 in the thickness direction X. The first gap 91 is formed between the portion of the first encapsulation portion 41a and the surface of the second portion 22 away from the first portion 21.

A portion of the second encapsulation portion 41b is located inside the second opening 23b and protects the second light-emitting structure 31b. A portion of the second encapsulation portion 41b is attached to the wall of the isolation structure 20 facing the second opening 23b, and at least partially climbs up to a side of the isolation structure 20 away from the substrate 10 in the thickness direction X. The second gap 92 is formed between the portion of the second encapsulation portion 41b and the surface of the second portion 22 away from the first portion 21.

In the display panel provided by the embodiments of the present application, since the thickness D2 of the second light-emitting structure 31b is larger than the thickness D1 of the first light-emitting structure 31a, the isolation structure 20 includes the first portion 21 and the second portion 22 sequentially arranged in the direction away from the substrate 10. In the thickness direction X, at least a portion of the first encapsulation portion 41a is spaced apart from and opposite to a surface of the second portion 22 away from the first portion 21 to form the first gap 91, at least a portion of the second encapsulation portion 41b is spaced apart from and opposite to the surface of the second portion 22 away from the first portion 21 to form the second gap 92 and the size of the first gap 91 is smaller than the size of the second gap 92. Thus, during a forming process of the display panel, the light-emitting structures 31 can be formed in an order from thin to thick. During this process, the light-emitting structures 31 with the latter thickness requirement will not cause damage to the encapsulation portions 41 of the formed light-emitting structures 31 with the previous thickness requirement during patterning, so as to reduce the probability of the display failure of parts of light-emitting structures 31 and improve the reliability of the display panel.

In some optional embodiments, the size of the first gap 91 is smaller than the thickness of the second light-emitting structure 31b. According to the above arrangement, the display failure of the previously formed light-emitting structure 31 can be avoided during the forming process of the display panel. In addition, the thickness of the first light-emitting structure 31a formed within the first opening 23a is smaller than the thickness of the second light-emitting structure 31b formed within the second opening 23b, so that the light-emitting structures 31 can be formed in an order from thin to thick.

In some optional embodiments, an orthographic projection of the second encapsulation portion 41b on the substrate 10 is spaced apart from an orthographic projection of the first encapsulation portion 41a on the substrate 10.

In some optional embodiments, the plurality of openings 23 further include a third opening 23c, the plurality of light-emitting structures 31 further include a third light-emitting structure 31c arranged in the third opening 23c, and a thickness D3 of the third light-emitting structure 31c is larger than the thickness D2 of the second light-emitting structure 31b in the thickness direction X.

The plurality of encapsulation portions 41 further include a third encapsulation portion 41c located on a side of the third light-emitting structure 31c away from the substrate 10. At least a portion of the third encapsulation portion 41c is spaced away from and opposite to the surface of the isolation structure 20 away from the substrate 10 to form a third gap 93. A size of the second gap 92 in the thickness direction X is smaller than a size of the third gap 93 in the thickness direction X.

In some optional embodiments, in the display panel provided by an embodiment of the present application, the size of the second gap 92 is smaller than the thickness D3 of the third light-emitting structure 31c. That is, the size d2 of the second gap 92 is smaller than the size d3 of the third gap 93, so as to avoid the display failure of the previously formed light-emitting structure 31 during the forming process.

In some optional embodiments, in the thickness direction X of the substrate 10, the size of the first gap 91 is larger than or equal to the thickness D1 of the first light-emitting structure 31a, the size of the second gap 92 is larger than or equal to the thickness D2 of the second light-emitting structure 31b, and the size of the third gap 93 is larger than or equal to the thickness D3 of the third light-emitting structure 31c.

According to the above arrangement, the display panel provided by the embodiments of the present application can ensure that all the light-emitting material layers formed within the first gap 91, second gap 92 and third gap 93 for forming the light-emitting structures 31 can be etched off, ensure the forming quality and display effect of the display panel, and improve the reliability of the display panel.

Optionally, the color of the light emitted by the third light-emitting structure 31c may be different from each of the color of the light emitted by the first light-emitting structure 31a and the color of the light emitted by the second light-emitting structure 31b.

In the display panel provided by the embodiments of the present application, according to the above arrangement, when the plurality of light-emitting structures 31 of the display panel have three or more thickness specifications, the light-emitting structures 31 can be formed in the order from thin to thick. During this process, the light-emitting structures 31 with the latter thickness requirement will not cause damage to the encapsulation portions 41 of the formed light-emitting structures 31 with the previous thickness requirement during patterning, so as to reduce the probability of the display failure of parts of light-emitting structures 31 and improve the reliability of the display panel.

It can be understood that, in the display panel provided by the embodiments of the present application, two of the colors of the light emitted by the first light-emitting structure 31a, the second light-emitting structure 31b and the third light-emitting structure 31c may be different from another color, or three colors are different from one another, and the colors can be set according to the display requirement.

In some optional embodiments, in the display panel provided by the embodiments of the present application, colors of light emitted by the first light-emitting structure 31a, the second light-emitting structure 31b and the third emitting structure 31c are different from one another.

That is, all the colors of light emitted by the first light-emitting structure 31a, the second light-emitting structure 31b and the third emitting structure 31c are not same as one another.

In the display panel provided by the embodiments of the present application, according to the above arrangement, the diversified display requirement of the display panel can be effectively ensured. In addition, according to the above arrangement, when the display panel is formed, it is beneficial for the display panel to be formed step by step according to the colors. For example, the light-emitting structure 31 with a corresponding light-emitting color and the thinnest thickness can be formed firstly, then the light-emitting structure 31 with a corresponding light-emitting color and a second thin thickness can be formed, and finally, the light-emitting structure 31 with a corresponding light-emitting color and the thickest thickness can be formed, thereby effectively avoiding the damage to the encapsulation portions 41 of the light-emitting structures 31 and improving the reliability of the display panel.

In some optional embodiments, in the display panel provided by the embodiments of present application, the light emitted by the first light-emitting structure 31a includes blue light, the light emitted by the second light-emitting structure 31b includes green light, and the light emitted by the third light-emitting structure 31c includes red light.

According to the above arrangement, the display requirement of the display panel can be effectively ensured. In addition, based on the characteristics of the light-emitting materials with different light-emitting colors and the brightness requirements of the display panel for the light-emitting structures 31 with different colors, a thickness of the light-emitting structure 31 emitting the blue light is smaller than a thickness of the light-emitting structure 31 emitting the green light, and the thickness of the light-emitting structure 31 emitting the green light is smaller than a thickness of the light-emitting structure emitting the red light. Therefore, according to the above arrangement, on the basis of meeting the display requirement, the light-emitting structures 31 of the display panel are formed in the order from thin to thick during the forming process, so as to avoid the display failure of the light-emitting structures 31 formed previously during the forming process.

In some optional embodiments, in the display panel provided by an embodiment of the present application, the light-emitting structures 31 include an organic material layer 311 and a first electrode 312 located on a side of the organic material layer 311 away from the substrate 10. The material of the isolation structure 20 includes a metal material, and the first electrode 312 is in contact with and connected to the isolation structure 20.

Optionally, the isolation structure 20 includes the first portion 21 and the second portion 22 sequentially arranged in the direction away from the substrate 10. An orthographic projection of the first portion 21 on the substrate 10 is located within an orthographic projection of the second portion 22 on the substrate 10.

Optionally, the plurality of light-emitting structures 31 include the first light-emitting structure 31a, the second light-emitting structure 31b and the third light-emitting structure 31c. A thickness of an organic material layer 311 of the second light-emitting structure 31b is larger than a thickness of an organic material layer 311 of the first light-emitting structure 31a. In some embodiments, a thickness of a first electrode 312 of the first light-emitting structure 31a is smaller than a thickness of a first electrode 312 of the second light-emitting structure 31b.

Optionally, a thickness of the organic material layer 311 of the third light-emitting structure 31c is larger than the thickness of the organic material layer 311 of the second light-emitting structure 31b.

Optionally, a thickness of the first electrode 312 of the third light-emitting structure 31c is larger than a thickness of the first electrode 312 of the second light-emitting structure 31b.

In some optional embodiments, a length of a portion of the second portion 22 protruding from the first portion 21 towards the side facing the first opening 23a is L1, a length of a portion of the second portion 22 protruding from the first portion 21 towards the side facing the second opening 23b is L2, and L1<L2.

According to the above arrangement, during a forming process of the display panel, the light-emitting structures 31 can be formed in an order from thin to thick. During this process, the light-emitting structure 31 with the latter thickness requirement will not cause damage to the encapsulation portions 41 of the formed light-emitting structures 31 with the previous thickness requirement during patterning, so as to reduce the probability of the display failure of parts of light-emitting structures 31 and improve the reliability of the display panel.

In some optional embodiments, the plurality of openings 23 further include a third opening 23c, and the plurality of light-emitting structures 31 further include a third light-emitting structure 31c arranged in the third opening 23c. A thickness of the third light-emitting structure 31c is larger than the thickness of the second light-emitting structure 31b in the thickness direction X. A length of a portion of the second portion 22 protruding from the first portion 21 towards the side facing the third opening 23c is L3, and L2<L3.

In the display panel provided by the embodiments of the present application, according to the above arrangement, when the plurality of light-emitting structures 31 of the display panel have three or more thickness specifications, the light-emitting structures 31 can be formed in the order from thin to thick. During this process, the light-emitting structure 31 with the latter thickness requirement will not cause damage to the encapsulation portion 41 of the formed light-emitting structure 31 with the previous thickness requirement during patterning, so as to reduce the probability of the display failure of parts of light-emitting structures 31 and improve the reliability of the display panel.

As shown in FIG. 1 to FIG. 6, embodiments of the present application further provide a display panel including a substrate 10, an isolation structure 20, a light-emitting function layer 30 and a first encapsulation layer 40. The isolation structure 20 is arranged on a side of the substrate 10 in a thickness direction X thereof, the isolation structure 20 surrounds and forms a plurality of openings 23, and the plurality of openings 23 include a first opening 23a and a second opening 23b. The light-emitting function layer 30 is arranged on the substrate 10, the light-emitting function layer 30 includes a plurality of light-emitting structures 31, and the plurality of light-emitting structures 31 include a first light-emitting structure 31a arranged in the first opening 23a and a second light-emitting structure 31b arranged in the second opening 23b. The first encapsulation layer 40 includes a plurality of encapsulation portions 41 corresponding to the light-emitting structures 31, respectively, the encapsulation portions 41 are located on a side of the light-emitting structures 31 away from the substrate 10, the encapsulation portions 41 are contact with a side wall of the isolation structure 20 facing the openings and extending to a side of the isolation structure 20 away from the substrate 10 along the side wall, and the plurality of encapsulation portions 41 are spaced apart from one another and include a first encapsulation portion 41a located on a side of the first light-emitting structure 31a away from the substrate 10 and a second encapsulation portion 41b located on a side of the second light-emitting structure 31b away from the substrate 10. In the thickness direction X, at least a portion of the first encapsulation portion 41a is spaced apart from and opposite to a surface of the isolation structure 20 away from the substrate 10 to form a first gap, and a size of the first gap in the thickness direction X is smaller than a thickness of the second light-emitting structure 31b.

In the display panel provided by an embodiment of the present application, according to the above arrangement, during a forming process of the display panel, the light-emitting structures 31 can be formed in an order from thin to thick. During this process, the light-emitting structure 31 with the latter thickness requirement will not cause damage to the encapsulation portion 41 of the formed light-emitting structure 31 with the previous thickness requirement during patterning, so as to reduce the probability of the display failure of parts of light-emitting structures 31 and improve the reliability of the display panel.

In some optional embodiments, at least a portion of the second encapsulation portion is spaced away from and opposite to a surface of the isolation structure away from the substrate to form a second gap. The plurality of openings further include a third opening. The plurality of light-emitting structures further include a third light-emitting structure arranged in the third opening. A size of the second gap in the thickness direction is smaller than a thickness of the third light-emitting structure.

As shown in FIG. 1 to FIG. 6, embodiments of the present application further provide a display panel including a substrate 10, an isolation structure 20, a light-emitting function layer 30 and a first encapsulation layer 40. The isolation structure 20 is arranged on a side of the substrate 10 in a thickness direction X thereof, the isolation structure 20 surrounds and forms a plurality of openings 23, the plurality of openings 23 include a first opening 23a and a second opening 23b, the isolation structure 20 includes a first portion 21 and a second portion 22 sequentially arranged in a direction away from the substrate 10, an orthographic projection of the first portion 21 on the substrate 10 is located within an orthographic projection of the second portion 22 on the substrate 10, a length of a portion of the second portion 22 protruding from the first portion 21 towards a side facing the first opening 23a is L1, a length of a portion of the second portion 22 protruding from the first portion 21 towards a side facing the second opening 23b is L2, and L1<L2. The light-emitting function layer 30 is arranged on the substrate 10, the light-emitting function layer 30 includes a plurality of light-emitting structures 31, the plurality of light-emitting structures 31 include a first light-emitting structure 31a arranged in the first opening 23a and a second light-emitting structure 31b arranged in the second opening 23b. The first encapsulation layer 40 includes a plurality of encapsulation portions 41 corresponding to the light-emitting structures 31, respectively, the encapsulation portions 41 are located on a side of the light-emitting structures 31 away from the substrate 10, the encapsulation portions 41 are contact with a side wall of the first portion 21 facing the openings 23 and extending to a side of the second portion 22 away from the substrate 10 along the side wall, and the plurality of encapsulation portions are spaced apart from one another and include a first encapsulation portion 41a located on a side of the first light-emitting structure 31a away from the substrate 10 and a second encapsulation portion 41b located on a side of the second light-emitting structure 31b away from the substrate 10. In the thickness direction X, at least a portion of the first encapsulation portion 41a is spaced apart from and opposite to a surface of the isolation portion 20 away from the substrate 10 to form a first gap, and a size of the first gap in the thickness direction X is smaller than a thickness of the second light-emitting structure 31b.

The number of openings 23 can be set according to the display requirement of the display panel. There are a plurality of first openings 23a and a plurality of second openings 23b. The number of first openings 23a may be equal to the number of second openings 23b. Alternatively, the number of first openings 23a may be more than or less than the number of the second openings 23b.

The light emitted by the first light-emitting structure 31a and the light emitted by the second light-emitting structure 31b may be different, for example: the light emitted by the first light-emitting structure 31a may include blue light, and the light emitted by the second light-emitting structure 31b may include green light; or the light emitted by the first light-emitting structure 31a may include green light, and the light emitted by the second light-emitting structure 31b may include red light.

The first encapsulation layer 40 can be used to protect the light-emitting structures 31, thereby reducing the probability of water and oxygen invading the light-emitting structures 31, and improving the reliability of the light-emitting structures 31.

The first encapsulation layer 40 includes the plurality of encapsulation portions 41, which correspond to the light-emitting structures 31, respectively, to achieve the encapsulation of the light-emitting structures 31. In some embodiments, the plurality of light-emitting structures 31 correspond to the plurality of encapsulation portions 41, respectively, thereby achieving the independent encapsulation of the light-emitting structures 31. Alternatively, one encapsulation portion 41 correspond to the plurality of light-emitting structures 31, and the plurality of light-emitting structures 31 can be encapsulated through the one encapsulation portion 41. For example, the plurality of light-emitting structures 31 with the same color can be encapsulated through the one encapsulation portion 41.

A portion of the first encapsulation portion 41a is located inside the first opening 23a and protects the first light-emitting structure 31a. A portion of the first encapsulation portion 41a is attached to a wall of the isolation structure 20 facing the first opening 23a, and at least partially climbs up to a side of the isolation structure 20 away from the substrate 10 in the thickness direction X. The first gap 91 is formed between the portion of the first encapsulation portion 41a and the surface of the second portion 22 away from the first portion 21.

A portion of the second encapsulation portion 41b is located inside the second opening 23b and protects the second light-emitting structure 31b. A portion of the second encapsulation portion 41b is attached to the wall of the isolation structure 20 facing the second opening 23b, and at least partially climbs up to a side of the isolation structure 20 away from the substrate 10 in the thickness direction X. The second gap 92 is formed between the portion of the second encapsulation portion 41b and the surface of the second portion 22 away from the first portion 21.

In the display panel provided by the embodiments of the present application, the first gap 91 and the second gap 92 are formed by etching a light-emitting material layer, which forms the light-emitting structures 31, located between a surface of the second portion 22 on the side away from the first portion 21 and the first encapsulation layer 40 during the forming process of the display panel. The size d1 of the first gap 91 is smaller than the thickness of the second light-emitting structure 31b, that is, the size d1 of the first gap 91 is smaller than the size d2 of the second gap 92, thereby avoiding the display failure of the light-emitting structure 31 formed previously during the forming process. In addition, it can ensure that the thickness of the first light-emitting structure 31a formed in the first opening 23a is smaller than the thickness of the second light-emitting structure 31b formed in the second opening 23b, and the light-emitting structures 31 can be formed in the order from thin to thick.

In some optional embodiments, in the display panel provided by an embodiment of the present application, an orthographic projection of the first encapsulation portion 41a on the substrate 10 is spaced apart from an orthographic projection of the second encapsulation portion 41b on the substrate 10. The plurality of openings 23 further include a third opening 23c, and the plurality of light-emitting structures 31 further include a third light-emitting structure 31c arranged in the third opening 23c. In the thickness direction X, a thickness of the third light-emitting structure 31c is larger than the thickness of the second light-emitting structure 31b. A length of a portion of the second portion 22 protruding from the first portion 21 towards a side facing the third opening 23c is L3, and L2<L3. The plurality of encapsulation portions 41 further include a third encapsulation portion 41c located on a side of the third light-emitting structure 31c away from the substrate 10. At least a portion of the third encapsulation portion 41c is spaced apart from and opposite to a surface of the second portion 22 away from the first portion 21 to forming a third gap 93, and a size of the second gap 92 is smaller than a size of the third gap of 93.

A portion of the third encapsulation portion 41c is located inside the third opening 23c and protects the third light-emitting structure 31c. A portion of the third encapsulation portion 41c is attached to the wall of the isolation structure 20 facing the third opening 23c, and at least partially climbs up to the side of the isolation structure 20 away from the substrate 10 in the thickness direction X. The third gap 93 is formed between the portion of the third encapsulation portion 41c and the surface of the second portion 22 away from the first portion 21.

In the display panel provided by the embodiments of the present application, the third gap 93 is also formed by etching a light-emitting material layer, which forms the light-emitting structures 31, located between a surface of the second portion 22 on the side away from the first portion 21 and the encapsulation portions 41 during the forming process of the display panel. The size d2 of the second gap 92 is smaller than the size d3 of the third gap 93, so that it can be ensured that the thickness of the second light-emitting structure 31b formed in the second opening 23b is smaller than the thickness of the third light-emitting structure 31c formed in the third opening 23c, and the light-emitting structures 31 can be formed in an order from thin to thick.

Optionally, in the thickness direction X, the thickness of the second light-emitting structure 31b is larger than the thickness of the first light-emitting structure 31a, and/or the thickness of the third light-emitting structure 31c is larger than the thickness of the second light-emitting structure 31b.

Optionally, in the thickness direction X, the size of the first gap 91 is larger than or equal to the thickness of the first light-emitting structure 31a, and/or the size of the second gap 92 is larger than or equal to the thickness of the second light-emitting structure 31b, and/or the size of the third gap 93 is larger than or equal to the thickness of the third light-emitting structure 31c.

Optionally, the color of the light emitted by the third light-emitting structure 31c may be different from each of the color of the light emitted by the first light-emitting structure 31a and the color of the light emitted by the second light-emitting structure 31b.

In the display panel provided by the embodiments of the present application, according to the above arrangement, when the plurality of light-emitting structures 31 of the display panel have three or more thickness specifications, the light-emitting structures 31 can be formed in the order from thin to thick. During this process, the light-emitting structure 31 with the latter thickness requirement will not cause damage to the encapsulation portions 41 of the formed light-emitting structures 31 with the previous thickness requirement during patterning, so as to reduce the probability of the display failure of parts of light-emitting structures 31 and improve the reliability of the display panel.

It can be understood that, in the display panel provided by the embodiments of the present application, two of the colors of the light emitted by the first light-emitting structure 31a, the second light-emitting structure 31b and the third light-emitting structure 31c may be different from another color, or three colors are different from one another, and the colors can be set according to the display requirement.

In some optional embodiments, in the display panel provided by the embodiments of the present application, colors of light emitted by the first light-emitting structure 31a, the second light-emitting structure 31b and the third emitting structure 31c are different from one another.

That is, all the colors of light emitted by the first light-emitting structure 31a, the second light-emitting structure 31b and the third emitting structure 31c are not same as one another.

In the display panel provided by the embodiments of the present application, according to the above arrangement, the diversified display requirement of the display panel can be effectively ensured. In addition, according to the above arrangement, when the display panel is formed, it is beneficial for the display panel to be formed step by step according to the colors. For example, the light-emitting structure 31 with a corresponding light-emitting color and the thinnest thickness can be formed firstly, then the light-emitting structure 31 with a corresponding light-emitting color and a second thin thickness can be formed, and finally, the light-emitting structures 31 with a corresponding light-emitting color and the thickest thickness can be formed, thereby effectively avoiding the damage to the encapsulation portions 41 of the light-emitting structures 31 and improving the reliability of the display panel.

In some optional embodiments, in the display panel provided by the embodiments of present application, the light emitted by the first light-emitting structure 31a includes blue light, the light emitted by the second light-emitting structure 31b includes green light, and the light emitted by the third light-emitting structure 31c includes red light.

According to the above arrangement, the display requirement of the display panel can be effectively ensured. In addition, based on the characteristics of the light-emitting materials with different light-emitting colors and the brightness requirements of the display panel for the light-emitting structures 31 with different colors, a thickness of the light-emitting structure 31 emitting the blue light is smaller than a thickness of the light-emitting structure 31 emitting the green light, and the thickness of the light-emitting structure 31 emitting the green light is smaller than a thickness of the light-emitting structure emitting the red light. Therefore, according to the above arrangement, on the basis of meeting the display requirement, the light-emitting structures 31 of the display panel are formed in the order from thin to thick during the forming process, so as to avoid the display failure of the light-emitting structures 31 formed previously during the forming process.

In some optional embodiments, the display panel further includes a second encapsulation layer 50, which is arranged on a side of the first encapsulation layer 40 away from the substrate 10, the second encapsulation layer 50 covers the plurality of encapsulation portions 41, and at least a portion of the second encapsulation layer 50 is filled in the first gap 91, the second gap 92 and the third gap 93.

The first encapsulation layer 40 and the second encapsulation layer 50 are jointly used to achieve the encapsulation effect of the display panel, and the second encapsulation layer 50 is located on the side of the first encapsulation layer 40 away from the substrate 10. From the above content, it can be seen that the light-emitting structures 31 with different thicknesses may cause a non-flat surface on the side of the first encapsulation layer 40 away from the substrate 10, which can lead to an adverse effect on an upper film layer.

In view of this, in the manufacturing process in the embodiments of the present application, the size and shape of the second encapsulation layer 50 can be controlled, so that the second encapsulation layer 50 is provided as a whole surface structure, and the surface of the second encapsulation layer 50 on the side away from the substrate 10 can be parallel or substantially parallel to the plane where the substrate 10 is located, thereby reducing the impact on the subsequent manufacturing process for the film layer.

In some optional embodiments, the display panel provided by the embodiments of the present application, at least a portion of the second encapsulation layer 50 is filled in the first gap 91, the second gap 92 and the third gap 93, so that the strength and stability of the encapsulation structures can be ensured, and the protecting effect on the light-emitting structures 31 can be ensured.

As shown in FIG. 1 to FIG. 7, in some optional embodiments, a display panel provided by an embodiment of the present application includes a substrate 10, an isolation structure 20, a light-emitting function layer 30 and a first encapsulation layer 40. The isolation structure 20 is arranged on a side of the substrate 10 in a thickness direction X thereof, the isolation structure 20 surrounds and forms a plurality of openings 23, and the plurality of openings 23 include a first opening 23a and a second opening 23b. The light-emitting function layer 30 is arranged on the substrate 10, the light-emitting function layer 30 includes a plurality of light-emitting structures 31, the plurality of light-emitting structures 31 include a first light-emitting structure 31a arranged in the first opening 23a and a second light-emitting structure 31b arranged in the second opening 23b, a thickness of the second light-emitting structure 31b is larger than a thickness of the first light-emitting structure 31a in the thickness direction X. The first encapsulation layer 40 includes a plurality of encapsulation portions 41 corresponding to the light-emitting structures 31, respectively, the encapsulation portions 41 are located on a side of the light-emitting structures 31 away from the substrate 10, and the plurality of encapsulation portions 41 are spaced apart from one another, and include a first encapsulation portion 41a located on a side of the first light-emitting structure 31a away from the substrate 10 and a second encapsulation portion 41b located on a side of the second light-emitting structure 31b away from the substrate 10. On a cross section along the thickness direction X of the substrate 10 and perpendicular to an extending direction of the isolation structure 20 disposed around a circumferential direction of the first light-emitting structure 31a, a distance between an edge of the isolation structure 20 located in the circumferential direction of the first light-emitting structure 31a and an edge of an end of the first encapsulation portion 41a, in a direction parallel to the plane where the substrate 10 is located, is M1, on a cross section along the thickness direction X of the substrate 10 and perpendicular to an extending direction of the isolation structure 20 disposed around a circumferential direction of the second light-emitting structure 31b, a distance between an edge of the isolation 20 structure located in the circumferential direction of the second light-emitting structure 31b and an edge of the second encapsulation portion 41b, in the direction parallel to the plane where the substrate 10 is located, is M2, and M1<M2.

The number of openings 23 can be set according to the display requirement of the display panel. There are a plurality of first openings 23a and a plurality of second openings 23b. The number of first openings 23a may be equal to the number of second openings 23b. Alternatively, the number of first openings 23a may be more than or less than the number of the second openings 23b.

The light emitted by the first light-emitting structure 31a and the light emitted by the second light-emitting structure 31b may be different, for example: the light emitted by the first light-emitting structure 31a may include blue light, and the light emitted by the second light-emitting structure 31b may include green light; or the light emitted by the first light-emitting structure 31a may include green light, and the light emitted by the second light-emitting structure 31b may include red light.

The plurality of openings 23 surrounded and formed by the isolation structure 20 can correspond to the light-emitting structures 31 respectively, that is, one light-emitting structure 31 is located within each of openings 23. Alternatively, the plurality of light-emitting structures 31 can be arranged within one opening 23, for example, the plurality of light-emitting structures 31 with the same color can be arranged within one opening 23.

The first encapsulation layer 40 can be used to protect the light-emitting structures 31, thereby reducing the probability of water and oxygen invading the light-emitting structures 31, and improving the reliability of the light-emitting structures 31.

The first encapsulation layer 40 includes the plurality of encapsulation portions 41, which correspond to the light-emitting structures 31, respectively, to achieve the encapsulation of the light-emitting structures 31. In some embodiments, the plurality of light-emitting structures 31 correspond to the plurality of encapsulation portions 41, respectively, thereby achieving the independent encapsulation of the light-emitting structures 31. Alternatively, one encapsulation portion 41 correspond to the plurality of light-emitting structures 31, and the plurality of light-emitting structures 31 can be encapsulated through the one encapsulation portion 41. For example, the plurality of light-emitting structures 31 with the same color can be encapsulated through the one encapsulation portion 41.

The centroid can be understood as a geometric center of the orthographic projection of the first light-emitting structure 31a in the thickness direction X.

In the display panel provided by an embodiment of the present application, on the cross section along the thickness direction X of the substrate 10 and perpendicular to the extending direction of the isolation structure 20 disposed around the circumferential direction of the first light-emitting structure 31a, the distance between the edge of the isolation structure 20 located in the circumferential direction of the first light-emitting structure 31a and the edge of the end of the first encapsulation portion 41a, in the direction parallel to the plane where the substrate 10 is located, is M1, on the cross section along the thickness direction X of the substrate 10 and perpendicular to the extending direction of the isolation structure 20 disposed around the circumferential direction of the second light-emitting structure 31b, the distance between an edge of the isolation 20 structure located in the circumferential direction of the second light-emitting structure 31b and the edge of the second encapsulation portion 41b, in the direction parallel to the plane where the substrate 10 is located, is M2, and M1<M2. Thus, during a forming process of the display panel, the light-emitting structures 31 can be formed in an order from thin to thick. During this process, the light-emitting structure 31 with the latter thickness requirement will not cause damage to the encapsulation portions 41 of the formed light-emitting structures 31 with the previous thickness requirement during patterning, so as to reduce the probability of the display failure of parts of light-emitting structures 31 and improve the reliability of the display panel.

In some optional embodiments, the isolation structure 20 includes a first portion 21 and a second portion 22 sequentially arranged in a direction away from the substrate 10. An orthographic projection of the first portion 21 on the substrate 10 is located within an orthographic projection of the second portion 22 on the substrate 10. A length of a portion of the second portion 22 protruding from the first portion 21 towards a side facing the first opening 23a is L1, a length of a portion of the second portion 22 protruding from the first portion 21 towards a side facing the second opening 23b is L2, and L1<L2.

Optionally, the plurality of openings 23 further include a third opening 23c, the plurality of light-emitting structures 31 further include a third light-emitting structure 31c arranged in the third opening 23c, and a thickness of the third light-emitting structure 31c is larger than the thickness of the second light-emitting structure 31b in the thickness direction X. The plurality of encapsulation portions 41 further include a third encapsulation portion 41c located on a side of the third light-emitting structure 31c away from the substrate 10. On a cross section along the thickness direction X of the substrate 10 and perpendicular to an extending direction of the isolation structure 20 disposed around a circumferential direction of the third light-emitting structure 31c, a distance between an edge of the isolation structure 20 located in the circumferential direction of the third light-emitting structure 31c and an edge of the third encapsulation portion 41c, in the direction parallel to the plane where the substrate 10 is located, is M3, and M2<M3.

According to the above arrangement, when the plurality of light-emitting structures 31 of the display panel have three or more size specifications, each of light-emitting structures 31 can also be formed in the order from thin to thick. In this process, the latter thickness required light-emitting structure 31 will not cause damage to the encapsulation portion 41 of the previously formed thickness required light-emitting structure 31 when patterned, avoiding the probability of display failure of some light-emitting structures 31 and improving the reliability of the display panel. During this process, the light-emitting structure 31 with the latter thickness requirement will not cause damage to the encapsulation portion 41 of the formed light-emitting structure 31 with the previous thickness requirement during patterning, so as to reduce the probability of the display failure of parts of light-emitting structures 31 and improve the reliability of the display panel.

Optionally, orthogonal projections of the plurality of encapsulation portions 41 on the substrate 10 are spaced apart from one another.

Optionally, the isolation structure 20 includes the first portion 21 and the second portion 22 sequentially arranged in the direction away from the substrate 10. The orthographic projection of the first portion 21 on the substrate 10 is located within the orthographic projection of the second portion 22 on the substrate 10. The length of the portion of the second portion 22 protruding from the first portion 21 towards the side facing the second opening 23b is L2, a length of a portion of the second portion 22 protruding from the first portion 21 towards a side facing the third opening 23c is L3, and L2<L3.

As shown in FIG. 1 to FIG. 6 and FIG. 8, in some optional embodiments, a display panel provided by an embodiment of the present application includes a substrate 10, an isolation structure 20, a light-emitting function layer 30 and a first encapsulation layer 40. The isolation structure 20 is arranged on a side of the substrate 10 in a thickness direction X thereof, the isolation structure 20 surrounds and forms a plurality of openings 23, and the plurality of openings 23 include a first opening 23a and a second opening 23b. The light-emitting function layer 30 is arranged on the substrate 10, the light-emitting function layer 30 includes a plurality of light-emitting structures 31, the plurality of light-emitting structures 31 include a first light-emitting structure 31a arranged in the first opening 23a and a second light-emitting structure 31b arranged in the second opening 23b, and a thickness of the second light-emitting structure 31b is larger than a thickness of the first light-emitting structure 31a in the thickness direction X. The first encapsulation layer 40 includes a plurality of encapsulation portions 41 corresponding to the light-emitting structures 31, respectively, the encapsulation portions 41 are located on a side of the light-emitting structures 31 away from the substrate 10, and the plurality of encapsulation portions 41 are spaced apart from one another, and include a first encapsulation portion 41a located on a side of the first light-emitting structure 31a away from the substrate 10 and a second encapsulation portion 41b located on a side of the second light-emitting structure 31b away from the substrate 10. An end of the first encapsulation portion 41a is provided with a first surface, and an end of the second encapsulation portion 41b is provided with a second surface. On a cross section along the thickness direction X of the substrate 10 and perpendicular to an extending direction of the isolation structure 20 disposed around a circumferential direction of the first light-emitting structure 31a, an inclination angle between the first surface and a plane where the substrate 10 is located is A1; on a cross section along the thickness direction X of the substrate 10 and perpendicular to an extending direction of the isolation structure 20 disposed around a circumferential direction of the second light-emitting structure 31b, an inclination angle between the second surface and the plane where the substrate 10 is located is A2, and A1<A2.

Optionally, the isolation structure 20 and the light-emitting function layer 30 are located on the same side of the substrate 10, and the isolation structure 20 surrounds and forms the plurality of openings 23. A size and a shape of the isolation structure 20 are not limited by the embodiments of the present application. Optionally, an orthogonal projection of the isolation structure 20 on the substrate 10 may be a mesh-like structure. Alternatively, in some embodiments, the orthogonal projection of the isolation structure 20 on the substrate 10 may be a plurality of independent circular structures, each of which is provided with the opening 23. All types of the isolation structure 20 mentioned above can meet the usage requirement of the display panel.

The plurality of openings 23 surrounded and formed by the isolation structure 20 can correspond to the light-emitting structures 31 respectively, that is, one light-emitting structure 31 is located within each of openings 23. Alternatively, the plurality of light-emitting structures 31 can be arranged within one opening 23, for example, the plurality of light-emitting structures 31 with the same color can be arranged within one opening 23.

The first encapsulation layer 40 can be used to protect the light-emitting structures 31, thereby reducing the probability of water and oxygen invading the light-emitting structures 31, and improving the reliability of the light-emitting structures 31.

The first encapsulation layer 40 includes the plurality of encapsulation portions 41, which correspond to the light-emitting structures 31, respectively, to achieve the encapsulation of the light-emitting structures 31. In some embodiments, the plurality of light-emitting structures 31 correspond to the plurality of encapsulation portions 41, respectively, thereby achieving the independent encapsulation of the light-emitting structures 31. Alternatively, one encapsulation portion 41 correspond to the plurality of light-emitting structures 31, and the plurality of light-emitting structures 31 can be encapsulated through the one encapsulation portion 41. For example, the plurality of light-emitting structures 31 with the same color can be encapsulated through the one encapsulation portion 41.

The centroid can be understood as a geometric center of the orthographic projection of the first light-emitting structure 31a in the thickness direction X.

In the display panel provided by an embodiment of the present application, the end of the first encapsulation portion 41a is provided with the first surface, and the end of the second encapsulation portion 41b is provided with the second surface. On the cross section along the thickness direction X of the substrate 10 and perpendicular to the extending direction of the isolation structure 20 disposed around the circumferential direction of the first light-emitting structure 31a, the inclination angle between the first surface and the plane where the substrate 10 is located is A1; on the cross section along the thickness direction X of the substrate 10 and perpendicular to the extending direction of the isolation structure 20 disposed around the circumferential direction of the second light-emitting structure 31b, the inclination angle between the second surface and the plane where the substrate 10 is located is A2, and A1<A2. Thus, during a forming process of the display panel, the light-emitting structures 31 can be formed in an order from thin to thick. During this process, the light-emitting structure 31 with the latter thickness requirement will not cause damage to the encapsulation portion 41 of the formed light-emitting structure 31 with the previous thickness requirement during patterning, so as to reduce the probability of the display failure of parts of light-emitting structures 31 and improve the reliability of the display panel.

In some optional embodiments, in the display panel provided by an embodiment of the present application, the plurality of openings 23 further include a third opening 23c. The plurality of light-emitting structures 31 further include a third light-emitting structure 31c arranged in the third opening 23c. A thickness of the third light-emitting structure 31c is larger than the thickness of the second light-emitting structure 31b in the thickness direction X. The plurality of encapsulation portions 41 further include a third encapsulation portion 41c located on a side of the third light-emitting structure 31c away from the substrate 10. An end of the third encapsulation portion 41c is provided with a third surface. On a cross section along the thickness direction X of the substrate 10 and perpendicular to an extending direction of the isolation structure 20 disposed around a circumferential direction of the third light-emitting structure 31c, an inclination angle between the third surface and the plane where the substrate 10 is located is A3, and A2<A3

According to the above arrangement, when the plurality of light-emitting structures 31 of the display panel have three or more size specifications, each of light-emitting structures 31 can also be formed in the order from thin to thick. In this process, the latter thickness required light-emitting structure 31 will not cause damage to the encapsulation portion 41 of the previously formed thickness required light-emitting structure 31 when patterned, avoiding the probability of display failure of some light-emitting structures 31 and improving the reliability of the display panel. During this process, the light-emitting structure 31 with the latter thickness requirement will not cause damage to the encapsulation portion 41 of the formed light-emitting structure 31 with the previous thickness requirement during patterning, so as to reduce the probability of the display failure of parts of light-emitting structures 31 and improve the reliability of the display panel.

Optionally, the isolation structure 20 includes the first portion 21 and the second portion 22 sequentially arranged in the direction away from the substrate 10. The orthographic projection of the first portion 21 on the substrate 10 is located within the orthographic projection of the second portion 22 on the substrate 10. The length of the portion of the second portion 22 protruding from the first portion 21 towards the side facing the second opening 23b is L2, a length of a portion of the second portion 22 protruding from the first portion 21 towards a side facing the third opening 23c is L3, and L2<L3.

Optionally, the isolation structure 20 includes a first portion 21 and a second portion 22 sequentially arranged in a direction away from the substrate 10. An orthographic projection of the first portion 21 on the substrate 10 is located within an orthographic projection of the second portion 22 on the substrate 10. A length of a portion of the second portion 22 protruding from the first portion 21 towards a side facing the first opening 23a is L1, a length of a portion of the second portion 22 protruding from the first portion 21 towards a side facing the second opening 23b is L2, and L1<L2.

Although the present application has been described with reference to preferred embodiments, various improvements can be made and components can be replaced with equivalents without departing from the scope of the present application. Especially, as long as there is no structural conflict, the various technical features mentioned in each of the embodiments can be combined in any way. The present application is not limited to the specific embodiments disclosed in the text, but includes all technical solutions falling within the scope of the claims.

What is claimed is:

1. A display panel, comprising:
a substrate;
an isolation structure, arranged on a side of the substrate in a thickness direction thereof, the isolation structure surrounding and forming a plurality of openings, and the plurality of openings comprising a first opening and a second opening, the isolation structure comprising a first portion and a second portion sequentially arranged in a direction away from the substrate, an orthographic projection of the first portion on the substrate being located within an orthographic projection of the second portion on the substrate, a length of a portion of the second portion protruding from the first portion towards a side facing the first opening being L1, a length of a portion of the second portion protruding from the first portion towards a side facing the second opening being L2, and L1<L2;
a light-emitting function layer, arranged on the substrate, the light-emitting function layer comprising a plurality of light-emitting structures, the plurality of light-emitting structures comprising a first light-emitting structure arranged in the first opening and a second light-emitting structure arranged in the second opening, a thickness of the second light-emitting structure being larger than a thickness of the first light-emitting structure in the thickness direction; and
a first encapsulation layer, comprising a plurality of encapsulation portions corresponding to the light-emitting structures, and the encapsulation portions being located on a side of the light-emitting structures away from the substrate.

2. The display panel according to claim 1, wherein the plurality of openings further comprise a third opening, the plurality of light-emitting structures further comprise a third light-emitting structure arranged in the third opening, a thickness of the third light-emitting structure is larger than the thickness of the second light-emitting structure in the thickness direction, a length of an edge of the second portion protruding from the first portion towards the third opening is L3, and L2<L3.

3. The display panel according to claim 2, wherein a wavelength of light emitted by the first light-emitting structure is shorter than a wavelength of light emitted by the second light-emitting structure; or
the wavelength of the light emitted by the first light-emitting structure is shorter than a wavelength of light emitted by the third light-emitting structure; or
the wavelength of the light emitted by the second light-emitting structure is shorter than the wavelength of the light emitted by the third light-emitting structure.

4. The display panel according to claim 1, wherein the encapsulation portions are in contact with a side wall of the first portion facing the openings and extends to a side of the second portion away from the substrate along the side wall;
the plurality of encapsulation portions are spaced apart from one another and comprise a first encapsulation portion located on a side of the first light-emitting structure away from the substrate, and a second encapsulation portion located on a side of the second light-emitting structure away from the substrate.

5. The display panel according to claim 4, wherein at least a portion of the first encapsulation portion is spaced apart from a surface of the second portion away from the first portion in the thickness direction to form a first gap, and a size of the first gap in the thickness direction is smaller than the thickness of the second light-emitting structure, or a size of the first gap in the thickness direction is larger than or equal to the thickness of the first light-emitting structure.

6. The display panel according to claim 5, wherein at least a portion of the second encapsulation portion is spaced apart from the surface of the second portion away from the first portion in the thickness direction to form a second gap; and
the size of the first gap in the thickness direction is smaller than a size of the second gap in the thickness direction.

7. The display panel according to claim 6, wherein the plurality of openings further comprise a third opening, and the plurality of light-emitting structures further comprise a third light-emitting structure arranged in the third opening;
the plurality of encapsulation portions further comprise a third encapsulation portion located on a side of the third light-emitting structure away from the substrate, and at least a portion of the third encapsulation portion is spaced apart from the surface of the second portion away from the first portion to form a third gap;
the size of the second gap in the thickness direction is smaller than a size of the third gap in the thickness direction; or
the size of the second gap in the thickness direction is smaller than the thickness of the third light-emitting structure.

8. The display panel according to claim 7, wherein the size of the second gap in the thickness direction is larger than or equal to the thickness of the second light-emitting structure, and the size of the third gap in the thickness direction is larger than or equal to the thickness of the third light-emitting structure.

9. The display panel according to claim 7, wherein a sum of the size of the first gap in the thickness direction and a thickness of the first encapsulation portion is less than the thickness of the second light-emitting structure;
and, a sum of the size of the second gap in the thickness direction and a thickness of the second encapsulation portion is less than the thickness of the third light-emitting structure.

10. The display panel according to claim 4, wherein on a cross section along the thickness direction and perpendicular to an extending direction of the isolation structure disposed around a circumferential direction of the first light-emitting structure, a distance between an edge of the isolation structure located in the circumferential direction of the first light-emitting structure and an edge of an end of the first encapsulation portion, in a direction parallel to the plane where the substrate is located, is M1, on a cross section along the thickness direction and perpendicular to an extending direction of the isolation structure disposed around a circumferential direction of the second light-emitting structure, a distance between an edge of the isolation structure located in the circumferential direction of the second light-emitting structure and an edge of the second encapsulation portion, in the direction parallel to the plane where the substrate is located, is M2, and M1<M2.

11. The display panel according to claim 4, wherein an end of the first encapsulation portion is provided with a first surface, and on a cross section along the thickness direction and perpendicular to an extending direction of the isolation structure disposed around a circumferential direction of the first light-emitting structure, an inclination angle between the first surface and a plane where the substrate is located is A1; an end of the second encapsulation portion is provided with a second surface, and on a cross section along the thickness direction and perpendicular to an extending direction of the isolation structure disposed around a circumferential direction of the second light-emitting structure, an inclination angle between the second surface and the plane where the substrate is located is A2; and A1<A2.

12. The display panel according to claim 1, wherein each of the light-emitting structures comprises an organic material layer and a first electrode located on a side of the organic material layer away from the substrate;
a thickness of the organic material layer of the second light-emitting structure is larger than a thickness of the organic material layer of the first light-emitting structure;
or a thickness of the first electrode of the first light-emitting structure is less than a thickness of the first electrode of the second light-emitting structure.

13. The display panel according to claim 12, wherein
the plurality of openings further comprise a third opening, and the plurality of light-emitting structures further comprise a third light-emitting structure located in the third opening,
a thickness of the organic material layer of the third light-emitting structure is larger than a thickness of the organic material layer of the second light-emitting structure;
or a thickness of the first electrode of the third light-emitting structure is larger than a thickness of the first electrode of the second light-emitting structure.

14. A display panel comprising:
a substrate;
an isolation structure, arranged on a side of the substrate in a thickness direction thereof, the isolation structure surrounding and forming a plurality of openings, and the plurality of openings comprising a first opening and a second opening;
a light-emitting function layer, arranged on the substrate, the light-emitting function layer comprising a plurality of light-emitting structures, the plurality of light-emitting structures comprising a first light-emitting structure arranged in the first opening and a second light-emitting structure arranged in the second opening, a thickness of the second light-emitting structure being larger than a thickness of the first light-emitting structure in the thickness direction; and
a first encapsulation layer, comprising a plurality of encapsulation portions corresponding to the light-emitting structures, the encapsulation portions being located on a side of the light-emitting structures away from the substrate, the encapsulation portions being in contact with a side wall of the isolation structure facing the openings and extending to a side of the isolation structure away from the substrate along the side wall, and the plurality of encapsulation portions comprising a first encapsulation portion located on a side of the first light-emitting structure away from the substrate and a second encapsulation portion located on a side of the second light-emitting structure away from the substrate;
in the thickness direction, at least a portion of the first encapsulation portion being spaced apart from and opposite to a surface of the isolation structure away from the substrate to form a first gap, and a size of the first gap in the thickness direction being smaller than a thickness of the second light-emitting structure.

15. The display panel according to claim 14, wherein at least a portion of the second encapsulation portion is spaced apart from the surface of the isolation structure away from the substrate to form a second gap, the plurality of openings further comprise a third opening, the plurality of light-emitting structures further comprise a third light-emitting structure arranged in the third opening, and a size of the second gap in the thickness direction is smaller than a thickness of the third light-emitting structure.

16. A method of manufacturing a display panel, comprising:
forming an isolation structure on a side of a substrate in a thickness direction thereof, the isolation structure surrounding and forming a plurality of openings, and the plurality of openings comprising a first opening and a second opening;
forming a first encapsulation material layer and a first light-emitting structural layer with a first thickness on the substrate and the isolation structure;
removing at least a portion of the first encapsulation material layer and a portion of the first light-emitting structural layer outside the first opening to form a first light-emitting structure located within the first opening and a first encapsulation portion covering the first light-emitting structure;
forming a second encapsulation material layer and a second light-emitting structural layer with a second thickness on the substrate and the isolation structure, the second thickness being larger than the first thickness; and
removing at least a portion of the second encapsulation material layer and a portion of the second light-emitting structural layer outside the second opening to form a second light-emitting structure located within the second opening and a second encapsulation portion covering the second light-emitting structure.

17. The method of manufacturing the display panel according to claim 16, wherein in the step of forming the second encapsulation material layer and the second light-emitting structural layer with the second thickness on the substrate and the isolation structure, the second light-emitting structural layer is continuously arranged at an edge of the first encapsulation portion.

18. The method of manufacturing the display panel according to claim 17, wherein the second light-emitting structural layer comprises a second light-emitting material layer and a first electrode material layer located on a side of the second light-emitting material layer away from the substrate, and the first electrode material layer of the second light-emitting structural layer is continuously arranged at the edge of the first encapsulation portion.

19. The method of manufacturing the display panel according to claim 16, wherein in the step of forming the isolation structure on the side of the substrate in the thickness direction thereof and the isolation structure surrounding and forming the plurality of openings, the plurality of openings further comprise a third opening, the method further comprises:
forming a third encapsulation material layer and third light-emitting structural layer with a third thickness on the substrate and the isolation structure, and the third thickness being larger than the second thickness; and
removing at least a portion of the third encapsulation material layer and a portion of the third light-emitting structural layer outside the third opening to form a third light-emitting structure located within the third opening and a third encapsulation portion covering the third light-emitting structure.

20. The method of manufacturing the display panel according to claim 19, the third light-emitting structural layer comprises a third light-emitting material layer and a first electrode material layer located on a side of the third light-emitting material layer away from the substrate, and the first electrode material layer of the third light-emitting structural layer is continuously arranged at the edge of the first encapsulation portion and/or an edge of the second encapsulation portion.
